(19) United States
(12) Patent Application Publication
(10) Pub. No.: US 2025/0125230 A1
(43) Pub. Date: Apr. 17, 2025

(54) CHIP ON FILM, MANUFACTURING METHOD THEREOF, AND DISPLAY APPARATUS

(71) Applicant: BOE TECHNOLOGY GROUP CO., LTD., Beijing (CN)

(72) Inventors: Xinhong LU, Beijing (CN); Yan QU, Beijing (CN); Shuilang DONG, Beijing (CN); Liuqing LI, Beijing (CN); Jingshang ZHOU, Beijing (CN); Guoteng LI, Beijing (CN); Baoman LI, Beijing (CN)

(21) Appl. No.: 18/728,485

(22) PCT Filed: Sep. 14, 2022
(86) PCT No.: PCT/CN2022/118764

§ 371 Date: Jul. 12, 2024

(51) Int. Cl. H01L 23/495

(52) U.S. Cl. CPC H01L 23/49572; H01L 23/49541

(57) ABSTRACT

Disclosed are a chip on film, a manufacturing method thereof, and a display apparatus. The chip on film includes: at least one substrate layer; a plurality of pads on the at least one substrate layer; a plurality of first leads on the at least one substrate layer and electrically connected to part of the pads; and a plurality of second leads on a side of each substrate layer away from the layer where the plurality of pads are located, and electrically connected to the rest of the pads.

### TECHNICAL FIELD

The present disclosure relates to the field of display technology, and particularly relates to a chip on film, a manufacturing method thereof, and a display apparatus.

### BACKGROUND

With the continuous development of the display technology, people have increasingly higher requirements on the display resolution (PPI). The emerging three-dimensional (3D) display technology, such as virtual reality (VR) and augmented reality (AR), has a particularly high resolution requirement due to the nature of near-to-eye display.

### SUMMARY

The chip on film, the manufacturing method thereof, and the display apparatus provided in the embodiments of the present disclosure specifically adopt the following solutions:

In one aspect, an embodiment of the present disclosure provides a chip on film, including:
at least one substrate layer;
a plurality of pads on the at least one substrate layer;
a plurality of first leads on the at least one substrate layer and electrically connected to part of the pads; and
a plurality of second leads on a side of each substrate layer away from a layer where the plurality of pads are located, and electrically connected to the rest of the pads.

In some embodiments, in the chip on film provided in the embodiments of the present disclosure, the plurality of first leads are between the at least one substrate layer and the layer where the plurality of pads are located.

In some embodiments, in the chip on film provided in the embodiments of the present disclosure, each of the first leads includes a first wire part and a first connection part integrally formed, and the first connection part is in contact with and electrically connected to a corresponding pad.

In some embodiments, in the chip on film provided in the embodiments of the present disclosure, an orthographic projection of the first connection part on the substrate layer substantially coincides with an orthographic projection of the pad electrically connected thereto on the substrate layer.

In some embodiments, the chip on film provided in the embodiments of the present disclosure further includes a plurality of first transfer electrodes each connected between the second lead and the pad.

In some embodiments, in the chip on film provided in the embodiments of the present disclosure, the plurality of first transfer electrodes and the plurality of first leads are in the same layer and made of the same material.

In some embodiments, in the chip on film provided in the embodiments of the present disclosure, an orthographic projection of each pad on the substrate layer is within an orthographic projection of one of the first transfer electrodes electrically connected thereto on the substrate layer.

In some embodiments, in the chip on film provided in the embodiments of the present disclosure, each of the second leads includes a second wire part and a second connection part integrally formed, and the second connection part is electrically connected to a corresponding pad through a corresponding first transfer electrode.

In some embodiments, in the chip on film provided in the embodiments of the present disclosure, the second connection part is in contact with and electrically connected to the first transfer electrode.

In some embodiments, the chip on film provided in the embodiments of the present disclosure further includes a plurality of raised structures on a side of a layer where the plurality of second leads are located away from the layer where the plurality of pads are located, wherein an orthographic projection of each raised structure on the substrate layer substantially coincides with an orthographic projection of a corresponding pad electrically connected to the second connection part on the substrate layer.

In some embodiments, in the chip on film provided in the embodiments of the present disclosure, the orthographic projection of the raised structure on the substrate layer is within an orthographic projection of the second connection part on the substrate layer.

In some embodiments, in the chip on film provided in the embodiments of the present disclosure, in a direction perpendicular to the substrate layer, the substrate layer exceeds the raised structure by a distance within 0.5 μm.

In some embodiments, the chip on film provided in the embodiments of the present disclosure further includes a plurality of second transfer electrodes embedded in the substrate layer, wherein the first transfer electrode is electrically connected to the second connection part through a corresponding second transfer electrode.

In some embodiments, the chip on film provided in the embodiments of the present disclosure further includes a plurality of third transfer electrodes in the same layer as the first transfer electrodes, and each connected between the first transfer electrode and the second transfer electrode.

In some embodiments, in the chip on film provided in the embodiments of the present disclosure, the first lead and the pad are integrally formed.

In some embodiments, in the chip on film provided in the embodiments of the present disclosure, each of the second leads includes a second wire part and a second connection part integrally formed, and the second connection part is in contact with and electrically connected to a corresponding pad.

In some embodiments, the chip on film provided in the embodiments of the present disclosure further includes a plurality of raised structures on a side of a layer where the plurality of second leads are located away from the layer where the plurality of pads are located, wherein an orthographic projection of each raised structure on the substrate layer has a shape substantially the same as an orthographic projection of a corresponding second lead on the substrate layer, and the orthographic projection of the raised structure on the substrate layer is within the orthographic projection of the second lead on the substrate layer.

In some embodiments, in the chip on film provided in the embodiments of the present disclosure, the raised structures are made of the same material as the pads.

In some embodiments, in the chip on film provided in the embodiments of the present disclosure, orthographic projections of the second leads on the substrate layer and orthographic projections of the first leads on the substrate layer are not overlapped with each other.

In some embodiments, in the chip on film provided in the embodiments of the present disclosure, the plurality of pads are arranged in an array, and any two adjacent rows of the pads are partially staggered along a preset direction.

In another aspect, an embodiment of the present disclosure further provides a method for manufacturing the chip on film as described above, including:
providing a rigid substrate, and forming a sacrificial layer on the rigid substrate;
sequentially forming at least one substrate layer, a plurality of first leads and a plurality of pads on the sacrificial layer, and forming a plurality of second leads each time before forming one substrate layer; wherein the plurality of first leads are electrically connected to part of the pads, and the plurality of second leads are electrically connected to the rest of the pads; and
removing the sacrificial layer to peel off the rigid substrate along with the sacrificial layer, to obtain the chip on film.

In some embodiments, in the method provided in the embodiments of the present disclosure, forming the plurality of first leads and the plurality of pads includes:
forming a plurality of first leads and a plurality of pads simultaneously through one patterning process, or sequentially forming a plurality of first leads and a plurality of pads through two patterning processes.

In some embodiments, in the method provided in the embodiments of the present disclosure, after forming one substrate layer each time and before forming the plurality of first leads, the method further includes:
etching the substrate layer and the second leads to expose copper layers of the second leads from the substrate layer.

In some embodiments, in the method provided in the embodiments of the present disclosure, after etching the substrate layer and the second leads each time to expose the copper layers of the second leads from the substrate layer, and before forming the plurality of first leads, the method further includes:
forming second transfer electrodes on the exposed copper layers of the second leads.

In some embodiments, in the method provided in the embodiments of the present disclosure, while forming the plurality of pads, the method further includes:
after the substrate layer and the second leads are etched for the last time, forming second transfer electrodes on the exposed copper layers of the second leads.

In some embodiments, in the method provided in the embodiments of the present disclosure, while forming the plurality of first leads, the method further includes:
forming first transfer electrodes, through which the second transfer electrodes are electrically connected to the pads corresponding to the second leads.

In some embodiments, in the method provided in the embodiments of the present disclosure, after forming the plurality of pads, the method further includes:
forming third transfer electrodes so that the second transfer electrodes are electrically connected to the pads corresponding to the second leads sequentially through the third transfer electrodes and the first transfer electrodes.

In some embodiments, in the method provided in the embodiments of the present disclosure, before forming the plurality of second leads for the first time, the method further includes:
forming a plurality of raised structures on the sacrificial layer, wherein orthographic projections of the raised structures on the rigid substrate substantially coincide with orthographic projections of the pads electrically connected to the second leads on the rigid substrate.

In some embodiments, in the method provided in the embodiments of the present disclosure, before forming the plurality of second leads for the first time, the method further includes:
forming a plurality of raised structures on the sacrificial layer, wherein an orthographic projection of each raised structure on the substrate layer has a shape substantially the same as an orthographic projection of a corresponding second lead on the substrate layer, and the orthographic projection of the raised structure on the substrate layer is within the orthographic projection of the second lead on the substrate layer.

In another aspect, an embodiment of the present disclosure provides a display apparatus, including the display substrate provided in the above embodiments of the present disclosure.

### BRIEF DESCRIPTION OF DRAWINGS

FIG. 1 is a schematic diagram of arranging pads and leads in a single metal layer in the existing art;

FIG. 2 is a schematic structural diagram of a chip on film according to an embodiment of the present disclosure;

FIG. 3 is a schematic structural diagram of a layer where first leads are located and a layer where second leads are located in the chip on film shown in FIG. 1;

FIG. 4 is a sectional view taken along line I-I′ in FIG. 1;

FIG. 5 is another schematic structural diagram of a chip on film according to an embodiment of the present disclosure;

FIG. 6 is a sectional view taken along line II-II′ in FIG. 5;

FIG. 7 is another schematic structural diagram of a chip on film according to an embodiment of the present disclosure;

FIG. 8 is a sectional view taken along line III-III′ in FIG. 7;

FIG. 9 is another schematic structural diagram of a chip on film according to an embodiment of the present disclosure;

FIG. 10 is a sectional view taken along line IV-IV′ in FIG. 9;

FIG. 11 is another schematic structural diagram of a chip on film according to an embodiment of the present disclosure;

FIG. 12 is a sectional view taken along line V-V′ in FIG. 11;

FIG. 13 is a schematic structural diagram of a layer where first leads are located in the chip on film shown in FIG. 1;

FIG. 14 is a schematic structural diagram of a layer where second leads are located in the chip on film shown in FIG. 1;

FIG. 15 is a schematic structural diagram of raised structures in the chip on film shown in FIG. 1;

FIG. 16 is a schematic structural diagram of the raised structures and the second leads in the chip on film shown in FIG. 10;

FIG. 17 is an image of a raised structure formed by an additive process according to an embodiment of the present disclosure;

FIG. 18 is an image of a raised structure formed by a subtractive process according to an embodiment of the present disclosure;

FIG. 19 is another schematic structural diagram of the chip on film shown in FIG. 4;

FIG. 20 is another schematic structural diagram of a chip on film according to an embodiment of the present disclosure;

FIG. 21 is a flowchart of a method for manufacturing a chip on film according to an embodiment of the present disclosure;

FIG. 22 is a schematic structural diagram of the chip on film shown in FIG. 4 during a manufacturing process;

FIG. 23 is another schematic structural diagram of the chip on film shown in FIG. 4 during a manufacturing process;

FIG. 24 is another schematic structural diagram of the chip on film shown in FIG. 4 during a manufacturing process;

FIG. 25 is another schematic structural diagram of the chip on film shown in FIG. 4 during a manufacturing process;

FIG. 26 is another schematic structural diagram of the chip on film shown in FIG. 4 during a manufacturing process;

FIG. 27 is a schematic structural diagram of a layer where second leads are located in the chip on film shown in FIG. 6;

FIG. 28 is a schematic structural diagram of the chip on film shown in FIG. 6 during a manufacturing process;

FIG. 29 is another schematic structural diagram of the chip on film shown in FIG. 6 during a manufacturing process;

FIG. 30 is a schematic structural diagram of a layer where second transfer electrodes are located in the chip on film shown in FIG. 6;

FIG. 31 is another schematic structural diagram of the chip on film shown in FIG. 6 during a manufacturing process;

FIG. 32 is a schematic structural diagram of a layer where first leads and first transfer electrodes are located in the chip on film shown in FIG. 6;

FIG. 33 is another schematic structural diagram of the chip on film shown in FIG. 6 during a manufacturing process;

FIG. 34 is a schematic structural diagram of a layer where pads are located in the chip on film shown in FIG. 6;

FIG. 35 is another schematic structural diagram of the chip on film shown in FIG. 6 during a manufacturing process;

FIG. 36 is a schematic structural diagram of a layer where second leads are located in the chip on film shown in FIG. 8;

FIG. 37 is a schematic structural diagram of the chip on film shown in FIG. 8 during a manufacturing process;

FIG. 38 is a schematic structural diagram of a layer where first leads and first transfer electrodes are located in the chip on film shown in FIG. 8;

FIG. 39 is another schematic structural diagram of the chip on film shown in FIG. 8 during a manufacturing process;

FIG. 40 is another schematic structural diagram of the chip on film shown in FIG. 8 during a manufacturing process;

FIG. 41 is a schematic structural diagram of a layer where pads and second transfer electrodes are located in the chip on film shown in FIG. 8;

FIG. 42 is another schematic structural diagram of the chip on film shown in FIG. 8 during a manufacturing process;

FIG. 43 is a schematic structural diagram of a layer where third transfer electrodes are located in the chip on film shown in FIG. 8;

FIG. 44 is another schematic structural diagram of the chip on film shown in FIG. 8 during a manufacturing process;

FIG. 45 is a schematic structural diagram of a layer where a first layer of second leads are located in the chip on film shown in FIG. 12;

FIG. 46 is a schematic structural diagram of the chip on film shown in FIG. 12 during a manufacturing process;

FIG. 47 is a schematic structural diagram of the chip on film shown in FIG. 12 during a manufacturing process;

FIG. 48 is a schematic structural diagram of a layer where a first layer of first transfer electrodes are located in the chip on film shown in FIG. 12;

FIG. 49 is a schematic structural diagram of the chip on film shown in FIG. 12 during a manufacturing process;

FIG. 50 is a schematic structural diagram of a layer where a second layer of second leads are located in the chip on film shown in FIG. 12;

FIG. 51 is a schematic structural diagram of the chip on film shown in FIG. 12 during a manufacturing process;

FIG. 52 is a schematic structural diagram of the chip on film shown in FIG. 12 during a manufacturing process;

FIG. 53 is a schematic structural diagram of a layer where a second layer of first transfer electrodes are located in the chip on film shown in FIG. 12;

FIG. 54 is a schematic structural diagram of the chip on film shown in FIG. 12 during a manufacturing process;

FIG. 55 is a schematic structural diagram of a layer where first leads and first transfer electrodes are located in the chip on film shown in FIG. 12;

FIG. 56 is a schematic structural diagram of the chip on film shown in FIG. 12 during a manufacturing process;

FIG. 57 is a schematic structural diagram of a layer where pads are located in the chip on film shown in FIG. 12;

FIG. 58 is a schematic structural diagram of the chip on film shown in FIG. 12 during a manufacturing process;

FIG. 59 is another schematic structural diagram of a chip on film according to an embodiment of the present disclosure; and

FIG. 60 is a schematic structural diagram of a display apparatus according to an embodiment of the present disclosure.

### DETAIL DESCRIPTION OF EMBODIMENTS

To make the objects, technical solutions and advantages of the embodiments of the present disclosure more apparent, the technical solutions according to the embodiments of the present disclosure will be clearly and completely described below with reference to the drawings of the embodiments of the present disclosure. It should be noted that the sizes and shapes of various components in the drawings are not to scale, but are merely intended to schematically illustrate the present disclosure. The same or similar reference signs refer to the same or similar elements or elements with the same or similar functions throughout the drawings. To keep the following description of the embodiments of the present disclosure clear and concise, detailed description of known functions and known components is omitted herein.

Unless otherwise defined, technical or scientific terms used herein are intended to have general meanings as understood by those skilled in the art to which the present disclosure belongs. The words “first”, “second” and similar terms used in the description and the claims of the present disclosure do not denote any order, quantity, or importance, but are used merely for distinguishing different components from each other. The word “comprising” or “including” or the like means that the element or item preceding the word contains elements or items that appear after the word or equivalents thereof, but does not exclude other elements or items. The words “inner”, “outer”, “upper”, “lower”, and the like are merely used to indicate a relative positional relationship, and when an absolute position of the described object is changed, the relative positional relationship may be changed accordingly.

At present, with the popularization of 4K and 8K display products, the corresponding resolution is getting higher and higher, along with an increasing number of signals on the corresponding integrated circuit (IC). Especially for three-dimensional display products, a better three-dimensional effect requires more views and thus a multiplied number of corresponding signal lines, posing higher challenges to ICs, chip on films (COFs), flexible printed circuits (FPCs), etc. However, limited by the current production and processing capacities of copper foils, a minimum line pitch of copper wires on the chip on film is about 18 μm, while a level of a pitch of the chip bonding process for the chip on film rolls in mass production is 24 μm, leading to a maximum of merely 4000 channels in the existing art. Therefore, to satisfy the requirement of a huge quantity of signal lines, the chip on film has to be laterally expanded (i.e., increased in length). On the other hand, however, limited by the wafer process, the cutting efficiency, and the like, a lateral dimension (i.e., length) of the chip can be made to 32 mm at most, making it impossible to correspond to more signal lines.

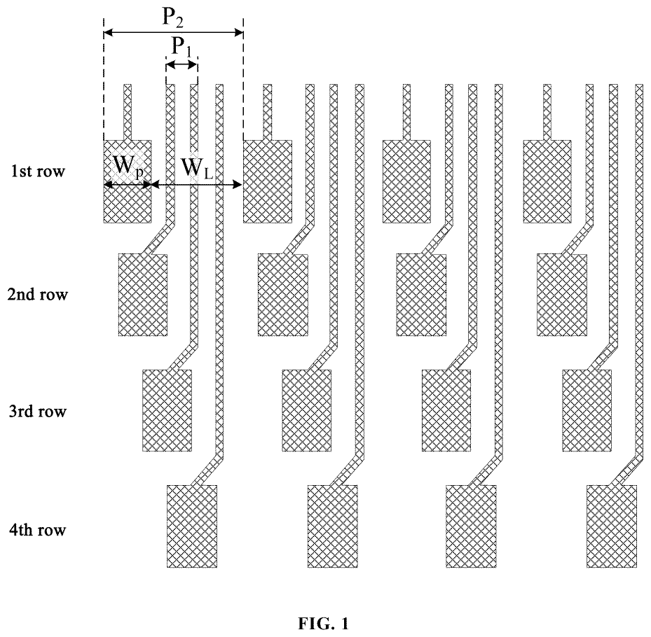

The length L of the IC bound by the chip on film is calculated by

$$L \geq \frac{m}{2 \times n} \times ( {W}_{p} + {W}_{L} ) , where {W}_{L} = ( n - 1 + 0.5 ) \times {P}_{1} ,$$

where Wₚ represents a pad width, and W_{L} represents a gap between adjacent pads; m is the number of pins, n is the number of rows, and P₁ is a line pitch. In the existing art, a maximum value of the IC length L is 32000 μm, a minimum value of the pad width Wₚ is 12 μm, a minimum value of the line pitch is 3.6 μm, and a sum of the pad width Wₚ and the pad gap W_{L} (corresponding to a lead pitch) is greater than or equal to 24 μm. As can be seen from the equation in conjunction with FIG. 1 and table 1, on the premise that the pads (also referred to as pins) and the leads of the chip on film are wired in the same layer, and given the same number n of rows, both the line pitch and the lead pitch are further compressed as the number of pads increases, readily making it reach the process limit of the current production line, to which the only solution is to increase the number n of rows of the pads. However, with an increased number n of rows of the pads, a width of the IC bonded to the chip on film will be increased, which will not only reduce the chip cutting efficiency, but also increase the difficulty in the subsequent inner lead bonding (ILB) process.

TABLE 1

| Number of | Number of | Lead | | | Line |
|---|---|---|---|---|---|
| pins | rows | Pitch/μm | Wₚ/μm | W_{L}/μm | Pitch/μm |
| 4000 | 2 | 32 | 12 | 20 | 13.3 |
| 8000 | 2 | 16 | 12 | 4 | 2.6 |
| | 3 | 24 | 12 | 12 | 4.8 |
| 10000 | 3 | 19.2 | 12 | 7.2 | 2.8 |
| | 4 | 25.6 | 12 | 13.6 | 3.8 |
| 12000 | 4 | 21.3 | 12 | 9.3 | 2.6 |
| | 5 | 26.6 | 12 | 14.6 | 3.2 |
| | 6 | 32 | 12 | 20 | 3.6 |
| 15000 | 6 | 25.6 | 12 | 13.6 | 2.4 |
| | 10 | 42.6 | 12 | 30.6 | 3.2 |
| | 15 | 64 | 12 | 52 | 3.6 |

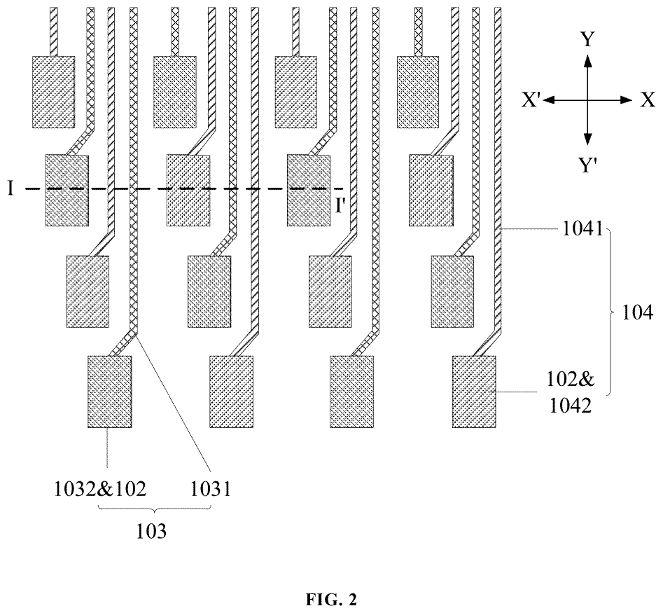

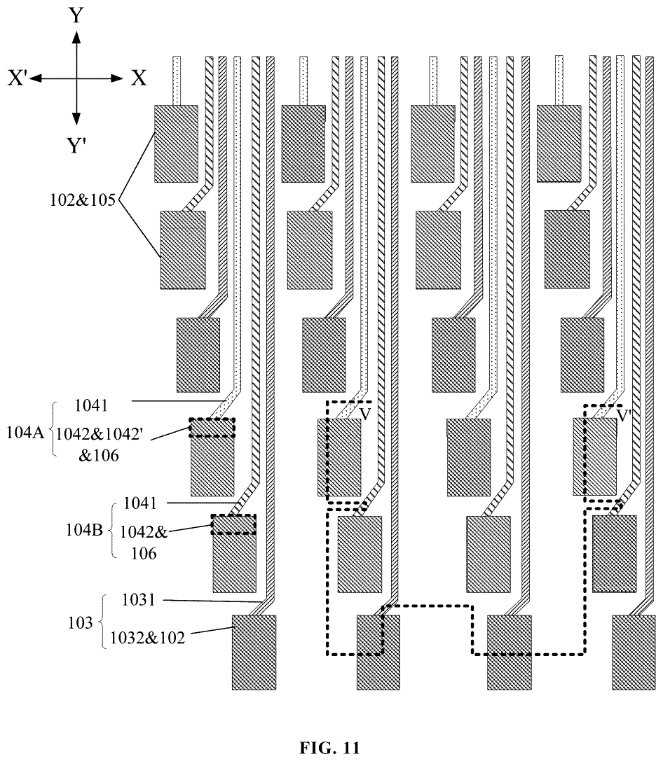

To solve the above technical problem in the existing art, an embodiment of the present disclosure provides a chip on film which, referring to FIGS. 2 to 12, includes at least one substrate layer 101, a plurality of pads 102, a plurality of first leads 103, and a plurality of second leads 104.

Optionally, the substrate layer 101 may be a flexible substrate made of polyimide (PI) or the like, so as to ensure a flexible function of the chip on film.

The plurality of pads 102 are provided on the at least one substrate layer 101. In some embodiments, the plurality of pads 102 may be formed by a subtractive plating process with a relatively low space requirement, and each pad 102 may have a thickness of 3 μm to 10 μm, for example, 3 μm, 4 μm, 5 μm, 6 μm, 7 μm, 8 μm, 9 μm, 10 μm, or the like.

The plurality of first leads 103 are provided on the at least one substrate layer 101, and electrically connected to part of the pads 102. In some embodiments, a material of the first leads 103 includes a metal material that can be patterned by dry etching (with a small CD bias), such as titanium (Ti), molybdenum (Mo), aluminum (Al), or the like. Each first lead 103 may have a single-layer structure or a stacked structure. For example, the first lead 103 has a single-layer structure of Ti, Mo, or the like, or a stacked structure of Ti/Al/Ti, Mo/Al/Mo, or the like. Optionally, in a case where the first lead 103 has a stacked structure of Ti/Al/Ti, to minimize the resistance of the first lead 103, a thickness of the Ti layer may be set to 500 Å and a thickness of the Al layer may be set to 6000 Å.

The plurality of second leads 104 are located on a side of each substrate layer 101 away from the layer where the plurality of pads 102 are located. In other words, in the case of more than one substrate layer 101, each substrate layer 101 is provided with a plurality of second leads 104 on a side away from the layer where the plurality of pads 102 are located. Optionally, the plurality of second leads 104 are electrically connected to the rest of the pads 102 (i.e., the pads 102 not connected to the first leads 103). In some embodiments, to simplify the process and save the cost of raw materials, it may be selected that the plurality of second leads 104 have the same thickness and made of the same material as the plurality of first leads 103. In other embodiments, the second leads 104 may be made of a different material than the first leads 102. For example, each second lead 104 has a stacked structure consisting of Ti/Cu/Ti, and out of economic considerations, a thickness of the Cu layer may be 3000 Å to 6000 Å, for example, 3000 Å, 4000 Å, 5000 Å, 6000 Å, or the like, while a thickness of the Ti layer may set to be no more than 500 Å.

In the chip on film provided in the embodiments of the present disclosure, the plurality of pads 102, and the plurality of first leads 103 electrically connected to part of the pads 102, are disposed on one side of the substrate layer 101, and the plurality of second leads 104 electrically connected to the rest of the pads 102 are disposed on the other side of the substrate layer 101 away from the layer where the plurality of pads 102 are located, so that the space on both sides of the substrate layer 101 can be used for wiring. Compared with the technical solution of merely providing a plurality of pads 102 and a plurality of leads electrically connected thereto in the same layer on one side, the present disclosure increases the wiring space, and can, given the same number of pads 102 as in the existing art, increase the number of pads 102 in a single row by means of the increased wiring space, thereby reducing the number of rows of pads 102 as well as the difficulty in the process. In addition, given the same number of rows of pads 102 as in the existing art, an upper limit of the number of pads 102 can be increased by means of the increased wiring space, thereby increasing the number of signal lines electrically connected to the pads 102 in the display panel, and further improving the resolution of the display panel.

In some embodiments, in the chip on film provided in the embodiments of the present disclosure, as shown in FIGS. 4, 6, 8, 10 and 12, the layer where the plurality of first leads 103 are located is disposed between the at least one substrate layer 101 as a whole and the layer where the plurality of pads 102 are located, so that the layer where the plurality of pads 102 are located and the layer where the plurality of first leads 103 are located on the at least one substrate layer 101 are disposed in different layers. Further, since the plurality of second leads 104 are located on a side of the substrate layer 101 away from the layer where the plurality of pads 102 are located, the layer where the plurality of pads 102 are located, the layer where the plurality of first leads 103 are located, and the layer where the plurality of second leads 104 are located are disposed in different layers, thereby further increasing the wiring space.

In some embodiments, in the chip on film provided in the embodiments of the present disclosure, as shown in FIGS. 2 to 12, each first lead 103 includes a first wire part 1031 and a first connection part 1032 integrally formed, and the first connection part 1032 is in contact with and electrically connected to a corresponding pad 102. Optionally, to ensure a larger contact area between the first connection part 1032 and the pad 102, and accordingly a smaller contact resistance and a better electrical connection effect, an orthographic projection of the first connection part 1032 on the substrate layer 101 may be set to substantially coincide with an orthographic projection of the pad 102 electrically connected thereto on the substrate layer 101. It should be noted that in the embodiments of the present disclosure, due to limitations of the process conditions or influences of other factors such as measurement, the phrase “substantially coincide” may refer to exact coincidence, or coincidence within a certain deviation (for example, a deviation of ±2 μm), and therefore, it falls in the protection scope of the present disclosure as long as the “substantially coincide” relationship of the involved features are within the allowed error range.

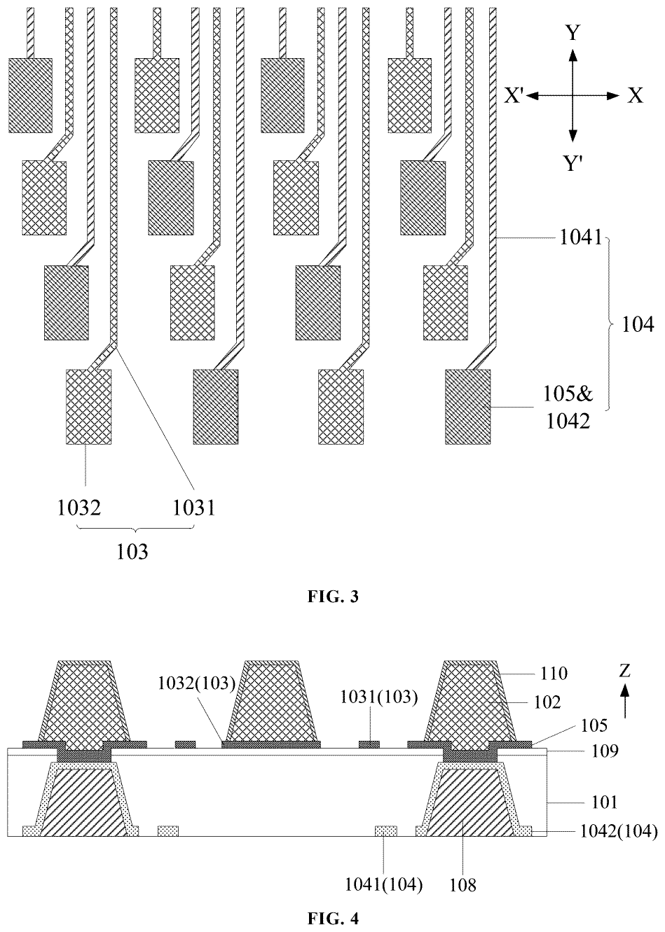

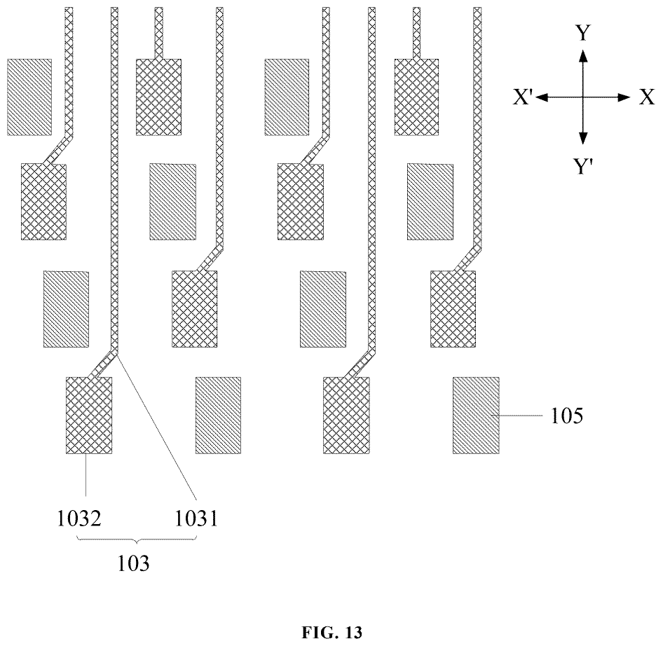

In some embodiments, as shown in FIGS. 3 to 8, 11 and 12, the chip on film provided in the embodiments of the present disclosure may further include a plurality of first transfer electrodes 105 connected between the second leads 104 and the pads 102. Optionally, as shown in FIG. 13, the plurality of first transfer electrodes 105 and the plurality of first leads 103 are disposed in the same layer and made of the same material. In other words, a conductive film layer for manufacturing the plurality of first transfer electrodes 105 and the plurality of first leads 103 is formed by one same film formation process, and then the plurality of first transfer electrodes 105 and the plurality of first leads 103 are formed by one patterning process with the same mask. That is, the one patterning process corresponds to one mask (also referred to as photomask). Depending on the specific pattern, one patterning process may include multiple exposure, development or etching processes. The formed plurality of first transfer electrodes 105 and plurality of first leads 103 are independent of each other, and may have the same thickness or different thicknesses. In the present disclosure, the first transfer electrodes 105 and the first leads 103 are electrically connected to different pads 102, and to improve the overall flatness of the pads 102, the transfer electrodes 105 and the first leads 103 may be made to have the same thickness.

In some embodiments, in the chip on film provided in the embodiments of the present disclosure, as shown in FIGS. 2 to 8, 11 and 12, an orthographic projection of each pad 102 on the substrate layer 101 is located within an orthographic projection of one of the first transfer electrodes 105 electrically connected thereto on the substrate layer 101. Since the layer where the plurality of first leads 103 are located is merely provided with the first leads 103 and the first transfer electrodes 105 (electrically connected to the respective pads 102 corresponding to the second leads 104), compared with the solution of providing all leads and all pads 102 in the same layer in the existing art, the layer where the first leads 103 are located has sufficient space for arrangement of the first transfer electrodes 105, so that the first transfer electrodes 105 may have a larger size than the pads 102, thereby facilitating the contact and electrical connection of the pads 102 corresponding to the second leads 104 with the first transfer electrodes 105.

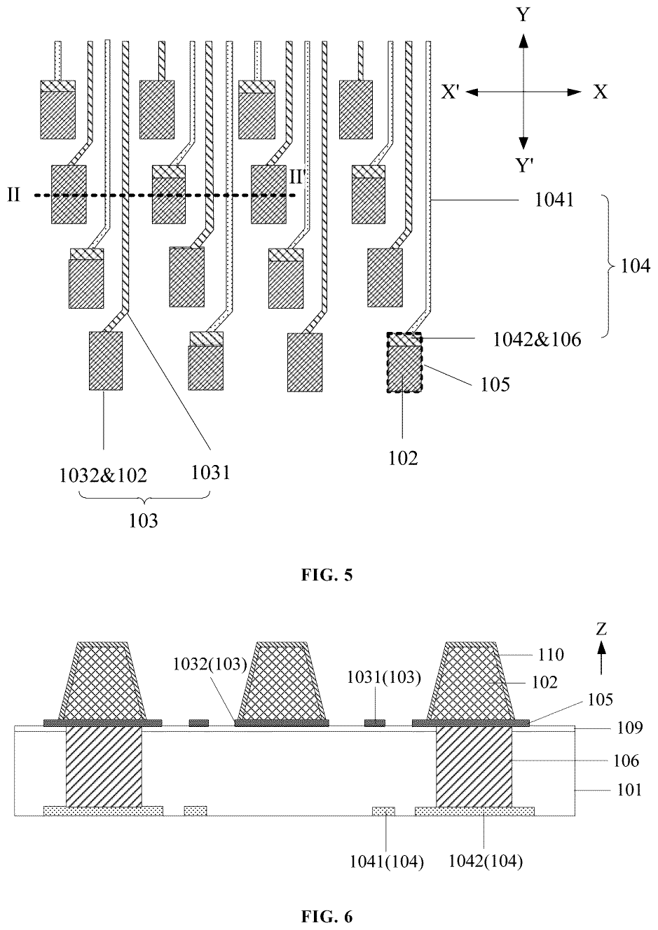

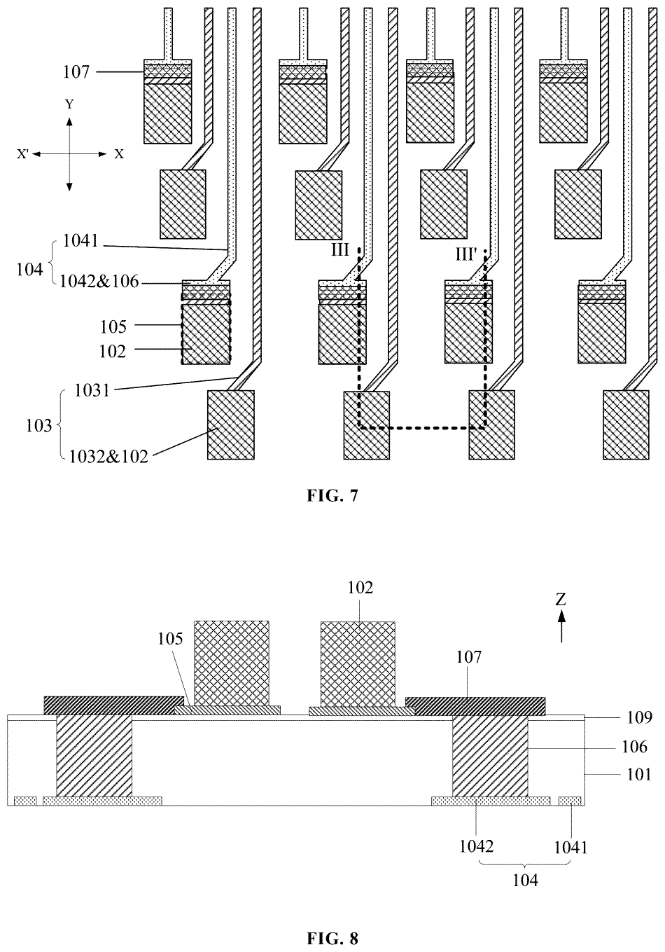

In some embodiments, in the chip on film provided in the embodiments of the present disclosure, as shown in FIGS. 2 to 8, each second lead 104 includes a second wire part 1041 and a second connection part 1042 integrally formed, and the second connection part 1042 is electrically connected to a corresponding pad 102 through a corresponding first transfer electrode 105. Optionally, as shown in FIG. 4, the second connection part 1042 is in contact with and electrically connected to the first transfer electrode 105 through a transfer hole running through the substrate layer 101. Alternatively, as shown in FIGS. 5 and 6, a plurality of second transfer electrodes 106 may be further included, the plurality of second transfer electrodes 106 are embedded in the substrate layer 101, and the first transfer electrode 105 is electrically connected to the second connection part 1042 through a corresponding second transfer electrode 106. Alternatively, as shown in FIGS. 7 and 8, a plurality of third transfer electrodes 107 may be further included, and the third transfer electrodes 107 are disposed in the same layer as the first transfer electrodes 105, and connected between the first transfer electrodes 105 and the second transfer electrodes 106, so that each first transfer electrode 105 is electrically connected to the second connection part 1042 sequentially through a corresponding third transfer electrode 107 and a corresponding second transfer electrode 106.

In some embodiments, the second transfer electrodes 106 in FIGS. 5 and 6 may be formed by an electroplating process to fill up the transfer hole in the substrate layer 101, thereby ensuring flatness of the subsequent layer where the first leads 103 are located. Optionally, while the second transfer electrodes 106 in FIGS. 7 and 8 are formed by an additive plating process to fill up the transfer hole in the substrate layer 101, the plurality of pads 102 having a bonding function may also be formed, so that one plating process is reduced compared to the solution of manufacturing the second transfer electrodes 106 and the pads 102 by two plating processes, respectively, thereby improving the productivity. Optionally, the second transfer electrode 106 is made of a material with good conductivity and low resistance, such as copper.

In some embodiments, as shown in FIGS. 4, 10, 14 and 15, the chip on film provided in the embodiments of the present disclosure may further include a plurality of raised structures 108 on a side of the layer where the plurality of second leads 104 are located away from the layer where the plurality of pads 102 are located. An orthographic projection of each raised structure 108 on the substrate layer 101 substantially coincides with an orthographic projection of a corresponding pad 102 electrically connected to the second connection part 1042 on the substrate layer. That is, the orthographic projections of the two are exactly coincident or within an error range due to the manufacturing process, measurement or other factors. In the present disclosure, the transfer hole in the substrate layer 101 is relatively deep, which is unfavorable for the first transfer electrode 105 to contact and be electrically connected to the second connection part 1042 through the transfer hole in the substrate layer 101. Therefore, a raised structure 108 for supporting the second connection part 1042 is provided in the present disclosure to reduce a depth of the hole in the substrate layer 101, thereby facilitating the contact and electrical connection between the second connection part 1042 and the first transfer electrode 105 through the transfer hole in the substrate layer 101. Optionally, an orthographic projection of the transfer hole in the substrate layer 101 on the substrate layer 101 is located within an orthographic projection of a surface of the raised structure 108 close to the layer where the pads 102 are located on the substrate layer 101.

In some embodiments, in the chip on film provided in the embodiments of the present disclosure, in a direction Z perpendicular to the substrate layer 101, the substrate layer 101 exceeds the raised structure 108 by a distance within 0.5 μm, equivalent to that the transfer hole in the substrate layer 101 has a depth no greater than 0.5 μm at the position corresponding to the raised structure 108, thereby facilitating the contact and electrical connection between the second connection part 1042 and the first transfer electrode 105 through the transfer hole in the substrate layer 101. Further, a raw material solution of the substrate layer 101 has a leveling property, and under the condition that the substrate layer 101 exceeds the raised structure 108 by a distance within 0.5 μm, the flatness of the substrate layer 101 can be better ensured.

Exemplarily, FIG. 17 shows a morphology of a raised structure 108 formed by an additive process, and FIG. 18 shows a morphology of a raised structure 108 formed by a subtractive process. It can be seen by comparison that the raised structure 108 in FIG. 17 has a substantially inverted trapezoidal section and an uneven surface, while the raised structure 108 in FIG. 18 has a trapezoidal section and a relatively flat surface. Since the raised structure 108 is an island, the raised structure 108 has substantially the same section in each direction. Considering that the raised structure 108 having the inverted trapezoidal morphology formed by the additive process is hard to be covered by the second connection part 1042, it is preferred to use the subtractive process having a relatively low space requirement to manufacture the raised structure 108 in the present disclosure. The raised structure 108 formed by the subtractive process has a more uniform film thickness, and optionally, the raised structure 108 has a thickness of 5 μm to 10 μm, for example, 5 μm, 6 μm, 7 μm, 8 μm, 9 μm, 10 μm, or the like. Accordingly, the thickness of the substrate layer 101 is 5.5 μm to 10.5 μm, for example, 5.5 μm, 6.5 μm, 7.5 μm, 8.5 μm, 9.5 μm, 10.5 μm, or the like.

In some embodiments, in the chip on film provided in the embodiments of the present disclosure, the raised structure 108 may be made of an insulating material, or may be made of the same conductive material as the pad 102. In the case that the raised structure 108 is made of the same material as the pad 102, the material cost can be saved, and the contact area between the second lead 104 and the raised structure 108 can be increased, so that an overall resistance between the second lead 104 and the raised structure 108 is reduced. Optionally, to prevent the raised structure 108 made of the same material as the pad 102 from being oxidized in a subsequent process of manufacturing the substrate layer 101, as shown in FIGS. 3 and 6, an orthographic projection of the raised structure 108 on the substrate layer 101 may be set to be located within an orthographic projection of the second connection part 1042 on the substrate layer 101, that is, the raised structure 108 is wrapped by the second connection part 1042, so as to protect the raised structure 108.

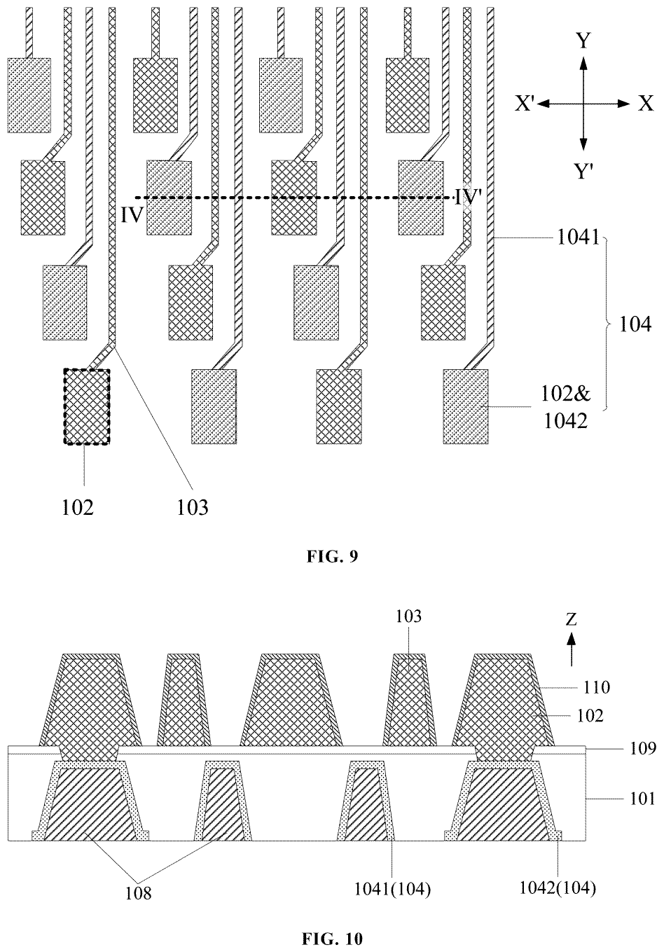

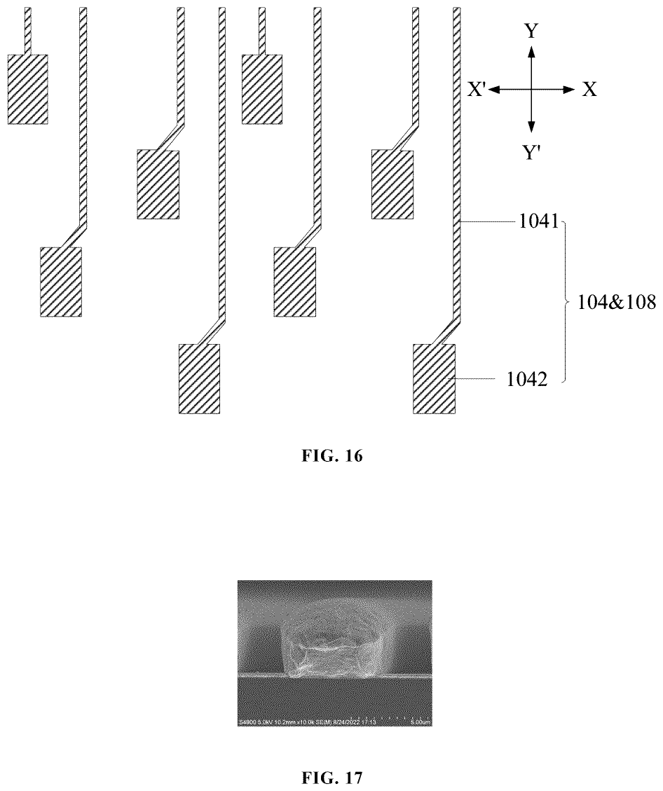

In some embodiments, in the chip on film provided in the embodiments of the present disclosure, as shown in FIGS. 9 and 10, when not too many pads are provided, the first leads 103 and the pads 102 may be disposed in the same layer and made of the same material, and optionally, the first leads 103 and the pads 102 are integrally formed, so as to avoid an additional film layer for the first leads 103, reduce the number of film layers, and improve flexibility of the chip on film. In this case, instead of being transferred to the pad 102 by the first transfer electrode 105, the second connection part 1042 of the second lead 104 can directly contact and be electrically connected to the pad 102. Optionally, to facilitate the electrical connection between the pad 102 and the second connection part 1042, a plurality of raised structures 108 may be still disposed on the side of the layer where the plurality of second leads 104 are located away from the layer where the plurality of pads 102 are located. In some embodiments, to share the mask and save the cost of the mask, as shown in FIG. 16, an orthographic projection of the raised structure 108 on the substrate layer 101 may be set to have a shape substantially the same as an orthographic projection of the second lead 104 on the substrate layer 101, while to protect the raised structure 108, the orthographic projection of the raised structure 108 on the substrate layer 101 may be set to be located within the orthographic projection of the second lead 104 on the substrate layer 101. In a specific implementation, in the process of respectively manufacturing the second lead 104 and the raised structure 108 with the same mask, a distance between the mask and an exposure lamp may be adjusted to make the second lead 104 and the raised structure 108 have the same shape but different sizes. Specifically, the distance between the mask and the exposure lamp in the process of manufacturing the raised structure 108 is controlled to be smaller than the distance between the mask and the exposure lamp in the process of manufacturing the second lead 104, so as to obtain a raised structure 108 having the same shape as the second lead 104 but a smaller size than the second lead 104.

In some embodiments, in the chip on film provided in the embodiments of the present disclosure, as shown in FIGS. 2, 5, 7, 9 and 11, orthographic projections of the second leads 104 on the substrate layer 101 and orthographic projections of the first leads 103 on the substrate layer 101 are not overlapped with each other, so as to avoid signal interference caused by coupling capacitance generated by overlapping of the two. Optionally, corresponding first wire parts 1031 and second wire parts 1041 electrically connected to the same column of pads 102 may be arranged alternately in a row direction X-X′, corresponding first wire parts 1031 and second wire parts 1041 electrically connected to odd columns of pads 102 are alternately arranged in the same manner, corresponding first wire parts 1031 and second wire parts 1041 electrically connected to even columns of pads 102 are alternately arranged in the same manner, the manner in which the first wire parts 1031 and the second wire parts 1041 electrically connected to odd columns of pads 102 are alternately arranged, is opposite to the manner in which the first wire parts 1031 and the second wire parts 1041 electrically connected to even columns of pads 102 are alternately arranged. It should be understood that since the first wire parts 1031 and the second wire parts 1041 are arranged in different layers, even if a distance between orthographic projections of the two on the substrate layer 101 is smaller than a distance between the leads arranged in the same layer in the existing art, a short circuit between the two can still be effectively avoided. On this basis, in the present disclosure, more leads are provided in the space of both the layer where the first wire parts 1031 is located and the layer where the second wire parts 1041 is located.

In some embodiments, in the chip on film provided in the embodiments of the present disclosure, as shown in FIGS. 2, 5, 7, 9 and 11, the plurality of pads 102 are arranged in an array, and any two adjacent rows of the pads 102 are partially staggered along a preset direction X. Compared with the solution of arranging various rows of pads 102 in a flush manner, a larger space is ensured for arrangement of the first wire parts 1031 and the second wire parts 1041 in the present disclosure by arranging any two adjacent rows of the pads 102 partially staggered along the preset direction X, thereby avoiding mutual overlapping of the first wire parts 1031 and the second wire parts 1041. Optionally, the pads 102 electrically connected to the first wire parts 1031 and the pads 102 electrically connected to the second wire parts 1041 are alternately arranged in the row direction X-X′ and a column direction Y-Y′.

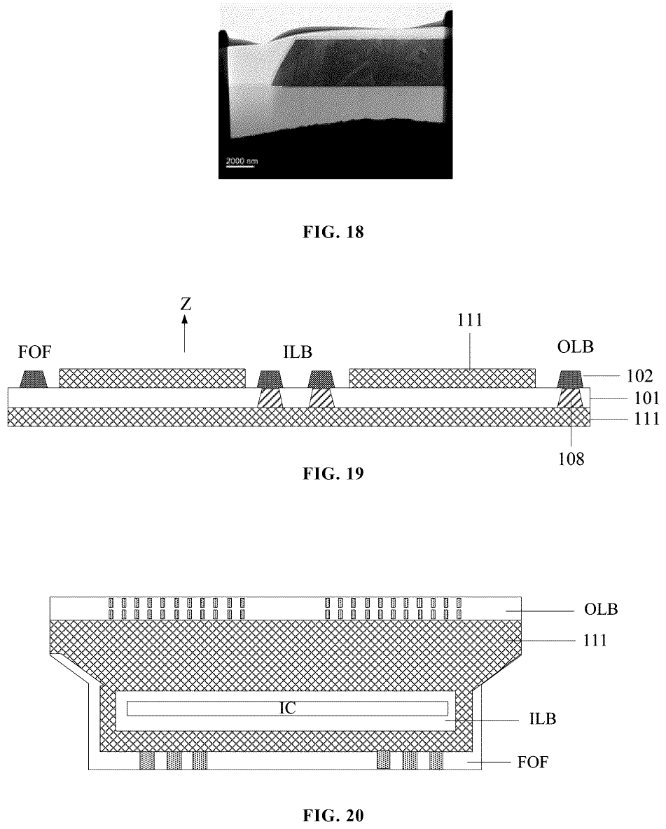

In some embodiments, in the chip on film provided in the embodiments of the present disclosure, as shown in FIGS. 4, 6, 8, 10 and 12, an inorganic layer 109 may be covered on the substrate layer 101 to block moisture. Further, to prevent the pads 102 from being oxidized and reduced in the conductivity, an anti-oxidation layer 110 may be plated on a surface of the pad 102. The anti-oxidation layer 110 may be made of stannum (Sn), gold (Au) or the like, and may have a thickness of 0.1 μm to 0.5 μm, for example, 0.1 μm, 0.2 μm, 0.3 μm, 0.4 μm, 0.5 μm or the like. Optionally, as shown in FIGS. 19 and 20, solder resin (SR) 111 may be coated by screen printing on both front and back surfaces of the substrate layer 101, the solder resin 111 above the substrate layer 101 exposes a first bonding region (OLB lead) for boding the chip on film and the panel, a second bonding region (ILB lead) for bonding the IC, and a third bonding region (FOF lead) for bonding the flexible printed circuit (FPC), while the solder resin 111 below the substrate layer 101 is applied over the entire surface. In some embodiments, the solder resin 111 on the front surface may be coated first, then the chip on film is removed from the glass substrate by laser lift off (LLO), and finally the solder resin 111 on the back surface is applied. In other embodiments, the chip on film may be removed from the glass substrate by laser lift off (LLO) first, and then the solder resin 111 on the front and back surfaces is formed, which is not limited herein.

Based on the same inventive concept, an embodiment of the present disclosure provides a method for manufacturing a chip on film. Since the method is used to solve the problem based on a principle similar to the chip on film, the implementation of the method provided in the embodiment of the present disclosure may refer to the implementation of the chip on film provided in the embodiments of the present disclosure, and repeated descriptions are omitted.

In some embodiments, as shown in FIG. 21, the method according to the embodiment of the present disclosure may include the following steps S2101 to S2103.

At S2101, providing a rigid substrate, and forming a sacrificial layer on the rigid substrate.

At S2102, sequentially forming at least one substrate layer, a plurality of first leads and a plurality of pads on the sacrificial layer, and forming a plurality of second leads each time before forming one substrate layer; where the plurality of first leads are electrically connected to part of the pads, and the plurality of second leads are electrically connected to the rest of the pads.

At S2103, removing the sacrificial layer to peel off the rigid substrate along with the sacrificial layer, to obtain the chip on film.

In some embodiments, in the method provided in the embodiments of the present disclosure, forming the plurality of first leads and the plurality of pads in step S2102 may be specifically implemented in two methods.

One possible implementation includes: forming a plurality of first leads and a plurality of pads simultaneously through one patterning process, so that the plurality of first leads and the plurality of pads are disposed in the same layer and made of the same material; and the other possible implementation includes: sequentially forming a plurality of first leads and a plurality of pads through two patterning processes, so that the layer where the plurality of first leads are located is positioned between the layer where the plurality of pads are located and a substrate layer closest to the layer where the pads are located.

In some embodiments, in the method provided in the embodiments of the present disclosure, in the above step S2102, after forming one substrate layer each time and before forming the plurality of first leads, the following step is further implemented:
etching the substrate layer and the second leads to expose copper layers of the second leads from the substrate layer, so as to grow second transfer electrodes on the copper layers.

In some embodiments, in the method provided in the embodiments of the present disclosure, after etching the substrate layer and the second leads each time to expose copper layers of the second leads from the substrate layer, and before forming the plurality of first leads, the following step is further implemented:
forming second transfer electrodes on the exposed copper layers of the second leads, so as to connect the second leads to subsequently formed pads through the second transfer electrodes.

In some embodiments, in the method provided in the embodiments of the present disclosure, while forming the plurality of pads in step S2102, the following step is further implemented:
after the substrate layer and the second leads are etched for the last time, forming second transfer electrodes on the exposed copper layers of the second leads, so that additional manufacturing of the second transfer electrode closest to the pads is omitted, and one procedure is saved.

In some embodiments, in the method provided in the embodiments of the present disclosure, while forming the plurality of first leads, the following step is further implemented:
forming first transfer electrodes, through which the second transfer electrodes are electrically connected to the pads corresponding to the second leads.

In some embodiments, in the method provided in the embodiments of the present disclosure, after forming the plurality of pads, the following step is further implemented:
forming third transfer electrodes so that the second transfer electrodes are electrically connected to the pads corresponding to the second leads sequentially through the third transfer electrodes and the first transfer electrodes.

In some embodiments, in the method provided in the embodiments of the present disclosure, before forming the plurality of second leads for the first time, the following step is further implemented:
forming a plurality of raised structures on the sacrificial layer, where orthographic projections of the raised structures on the rigid substrate substantially coincide with orthographic projections of the pads electrically connected to the second leads on the rigid substrate, or an orthographic projection of each raised structure on the substrate layer has a shape substantially the same as an orthographic projection of a corresponding second lead on the substrate layer, and the orthographic projection of the raised structure on the substrate layer is located within the orthographic projection of the second lead on the substrate layer.

To better understand the method provided in the embodiments of the present disclosure, a manufacturing process of the display substrate provided in the embodiments of the present disclosure will be described in detail below.

In some embodiments, the chip on film shown in FIG. 19 (corresponding to the chip on film shown in FIG. 4) may be manufactured by the following steps:

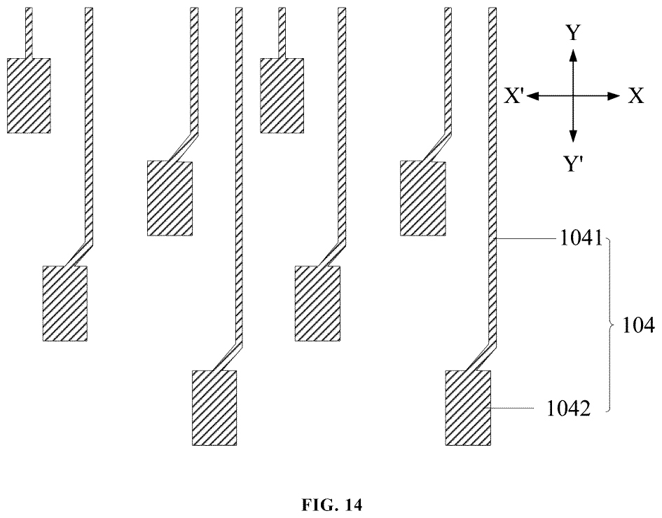

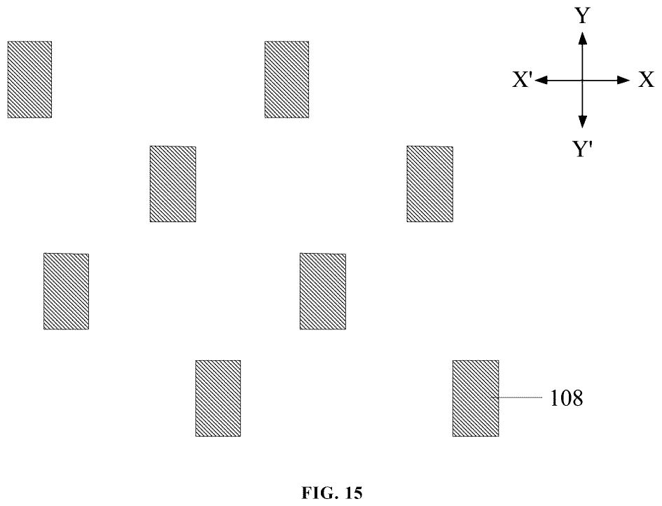

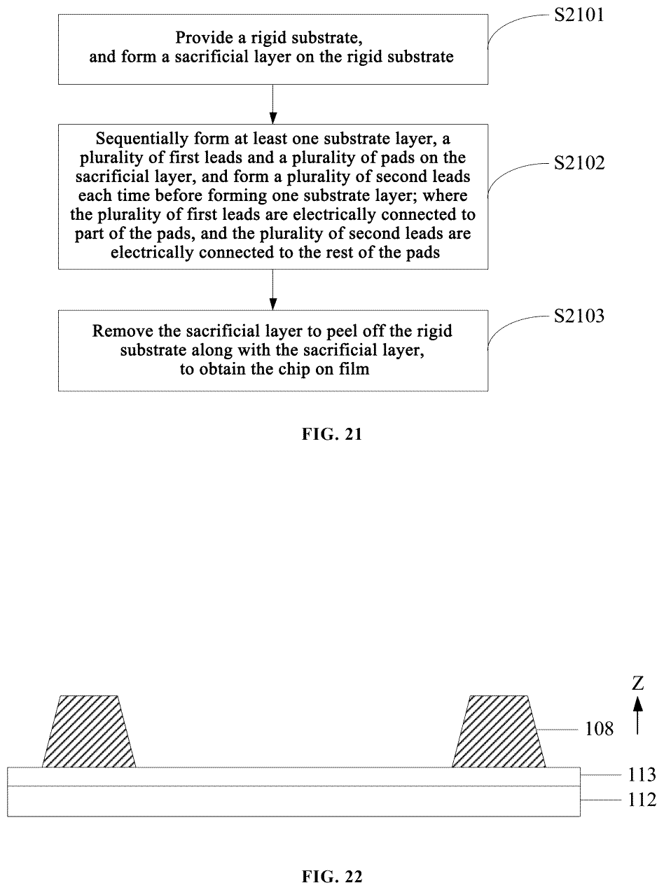

In first step, as shown in FIG. 22, a sacrificial layer 113 (de-bonding layer, DBL) is coated on a rigid substrate 112 (e.g., a glass substrate). The sacrificial layer 113 may be made of a polyimide system material, and have a thickness of 300 Å to 1000 Å, for example, 300 Å, 400 Å, 500 Å, 600 Å, 700 Å, 800 Å, 900 Å, 1000 Å, or the like. Then, a plurality of raised structures 108 (as shown in FIG. 15) are formed by electroplating on the sacrificial layer 113. The raised structures 108 are preferably processed by a subtractive process to ensure a uniform film thickness, and each raised structure 108 has a thickness of 5 μm to 10 μm, for example, 5 μm, 6 μm, 7 μm, 8 μm, 9 μm, 10 μm, or the like.

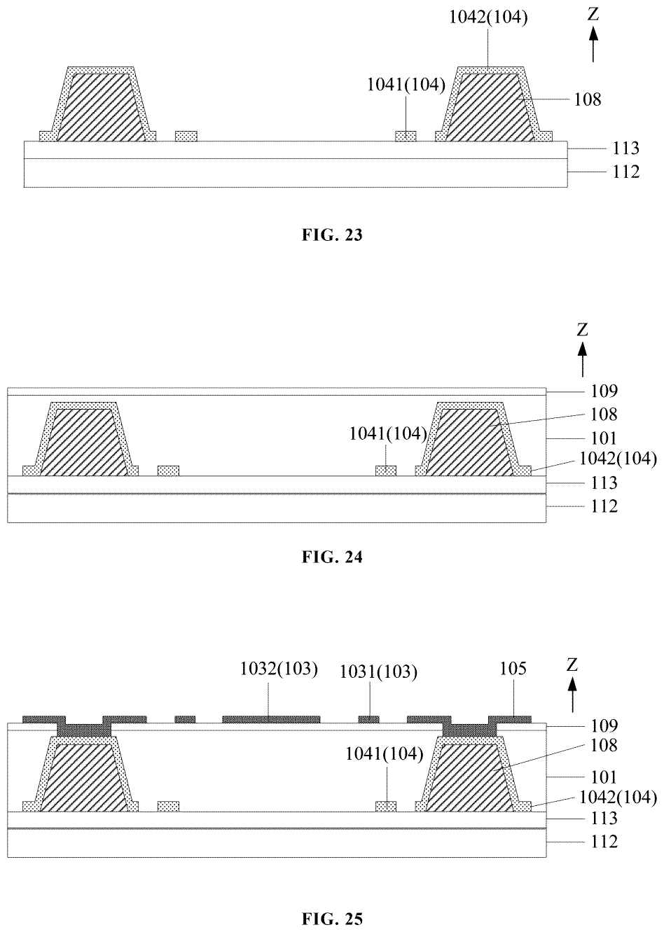

In a second step, as shown in FIGS. 14 and 23, a plurality of second leads 104 are formed. The second leads 104 are preferably made of a metal material that can be patterned by dry etching (with a small CD bias), such as Ti, Ti/Al/Ti, Mo/Al/Mo, etc., and has a thickness set based on the principle of minimizing the wire resistance. For example, a thickness of the Ti/Al/Ti may be set to 500 Å/6000 Å/500 Å, or the like. In particular, considering the subsequent high temperature manufacturing process of the substrate layer 101, the second leads 104 are desired to wrap the raised structures 108. Optionally, in this embodiment, each second lead 104 includes a second wire part 1041 and a second connection part 1042 integrally formed, and a corresponding raised structure 108 is wrapped by the second connection part 1042. In other words, an orthographic projection of the raised structure 108 on the rigid substrate 112 is located within an orthographic projection of the second connection part 1042 on the rigid substrate 112.

In a third step, as shown in FIG. 24, a substrate layer 101 is formed on the layer where the plurality of second leads 104 are located. The substrate layer 101 may be a flexible substrate made of, for example, polyimide, and have a thickness close to the raised structure 108. For example, the thickness of the substrate layer 101 is within 0.5 μm greater than the thickness of the raised structure 108. Since the raw material solution of the substrate layer 101 has a leveling property, and the substrate layer 101 is flat in regions other than the raised structures 108. Then, an inorganic layer 109 (buffer) may be deposited over the substrate layer 101 to isolate moisture.

In a fourth step, as shown in FIGS. 13 and 25, transfer holes running through the substrate layer 101 and the inorganic layer 109 are formed in the substrate layer 101 and the inorganic layer 109 at positions corresponding to the raised structures 108, and then a plurality of first leads 103 and a plurality of first transfer electrodes 105 are formed on the inorganic layer 109. An orthographic projection of each first transfer electrode 105 on the rigid substrate 112 may substantially coincide with an orthographic projection of a corresponding second connection part 1042 on the rigid substrate 112. That is, the orthographic projections of the two are exactly coincident or within an error range due to the manufacturing process, measurement or other factors. Optionally, it is selected that the layer where the plurality of first leads 103 and the plurality of first transfer electrodes 105 are located is made of the same material and has the same thickness as the layer where the plurality of second leads 104 are located.

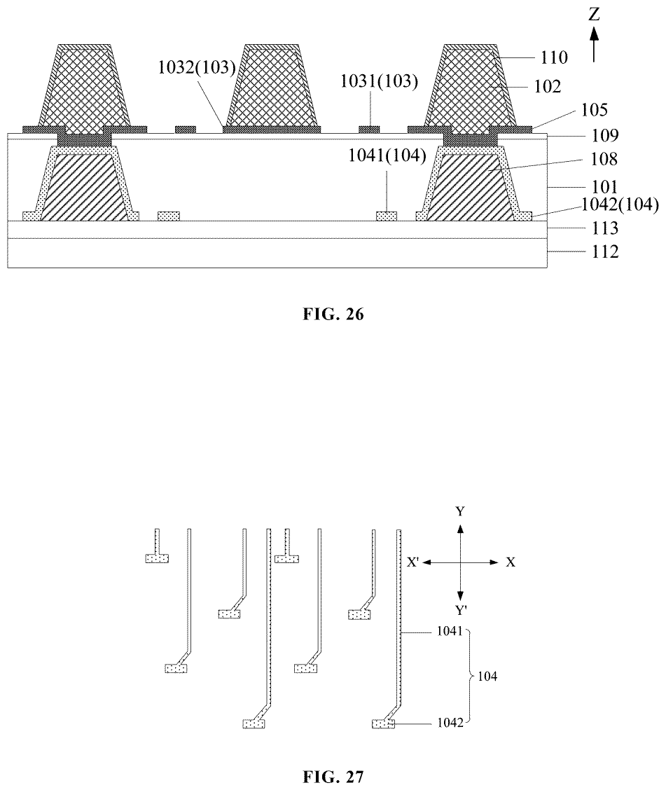

In a fifth step, as shown in FIGS. 2 and 26, a plurality of pads 102, as final bonding pads, are formed on the layer where the plurality of first leads 103 and the plurality of first transfer electrodes 105 are formed. Then, an anti-oxidation layer 110 is plated on a surface of each pad 102. The anti-oxidation layer 110 may be made of Sn or Au or the like, and have a thickness of 0.1 μm to 0.5 μm. Optionally, the plurality of pads 102 may be formed by a subtractive plating process with a relatively low space requirement, and each pad 102 may have a thickness of 3 μm to 10 μm.

In a sixth step, as shown in FIG. 4, the rigid substrate 112 is peeled off by laser lift off (LLO), and the plurality of second leads 104 and the plurality of raised structures 108 can be successfully separated from the rigid substrate 112 due to the presence of the sacrificial layer 113.

In a seventh step, as shown in FIG. 19, solder resin (SR) 111 is coated by screen printing on both front and back surfaces of the substrate layer 101, the solder resin 111 above the substrate layer 101 exposes a first bonding region (OLB lead) for boding the chip on film and the panel, a second bonding region (ILB lead) for bonding the IC, and a third bonding region (FOF lead) for bonding the flexible printed circuit (FPC), while the solder resin 111 below the substrate layer 101 is applied over the entire surface. In some embodiments, the solder resin 111 on the front surface may be coated first, then the chip on film is removed from the glass substrate by laser lift off (LLO), and finally the solder resin 111 on the back surface is applied. In other embodiments, the chip on film may be removed from the glass substrate by laser lift off (LLO) first, and then the solder resin 111 on the front and back surfaces is formed, which is not limited herein.

Therefore, the chip on film shown in FIG. 19 is completely formed.

The chip on film shown in FIG. 10 may be formed through similar steps to the above first to sixth steps, except that: first, the raised structure 108 in FIG. 10 has the same shape as the second lead 104, and the orthographic projection of the raised structure 108 is located within the orthographic projection of the second lead 104; and second, instead of manufacturing the first lead 103 separately, the first lead 103 is formed simultaneously with the pad 102 in FIG. 10, so that the first lead 103 and the pad 102 are disposed in the same layer and made of the same material, and the first transfer electrode 105 is omitted since the pad 102 is in contact with and electrically connected to the second connection part 1042. Optionally, to prevent oxidation of the first lead 103, an anti-oxidation layer 110 wrapping the first lead 103 may be formed simultaneously with an anti-oxidation layer 110 wrapping the pad 102.

In some embodiments, the chip on film shown in FIG. 6 may be manufactured by the following steps:

In a first step, a sacrificial layer 113 (de-bonding layer, DBL) is coated on a rigid substrate 112 (e.g., a glass substrate). The sacrificial layer 113 may be made of a polyimide system material, and have a thickness of 300 Å to 1000 Å, for example, 300 Å, 400 Å, 500 Å, 600 Å, 700 Å, 800 Å, 900 Å, 1000 Å, or the like.

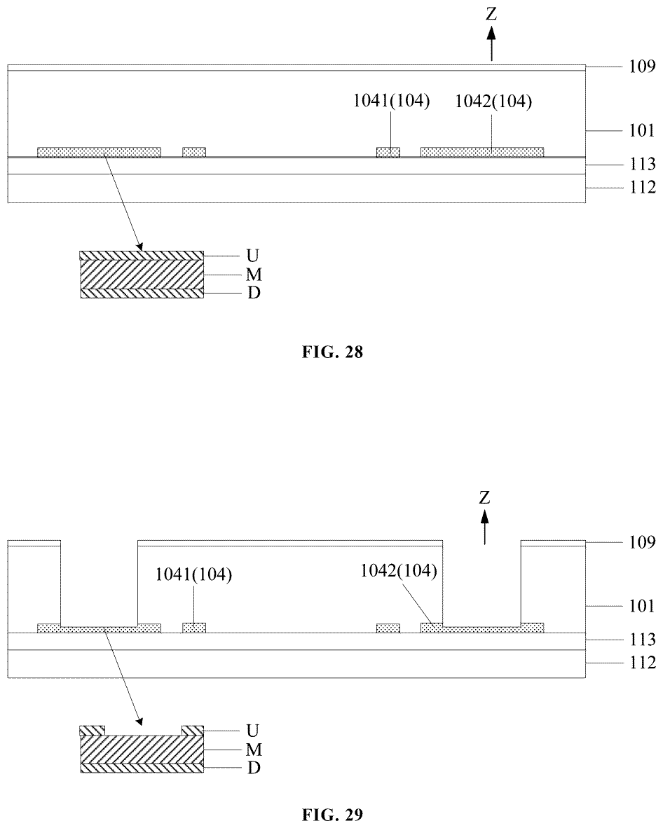

In a second step, as shown in FIGS. 27 and 28, a plurality of second leads 104 are formed on the sacrificial layer 113. Each second lead 104 includes a second wire part 1041 and a second connection part 1042. The second lead 104 has a three-layer metal structure, with an intermediate layer of copper and an uppermost/lowermost layer of a metal material that can be removed by a dry etching process, such as molybdenum (Mo), aluminum (Al), titanium (Ti), a molybdenum/nickel/titanium (MTD) alloy or the like, preferably Ti/Cu/Ti, and out of economic considerations, a thickness of the copper layer M may be 3000 Å to 6000 Å, while the upper metal layer U and the lower metal layer D may each have a thickness preferably not more than 500 Å. Subsequently, a substrate layer 101 and an inorganic layer 109 are formed on the plurality of second leads 104.

In a third step, as shown in FIG. 29, transfer holes are formed at positions corresponding to respective second connection parts 1042, and etching of the inorganic layer 109, the substrate layer 101, and the upper metal layer D at the positions corresponding to the second connection parts 1042 is implemented by a dry etching process for only one time. In particular, the upper metal layer D is completely removed to ensure that the copper metal can be electroplated subsequently to form the second transfer electrode 106. By forming the substrate layer 101 before forming the second transfer electrode 106, the oxidation effect of the high-temperature process of the substrate layer 101 on the second transfer electrode 106 is effectively avoided.

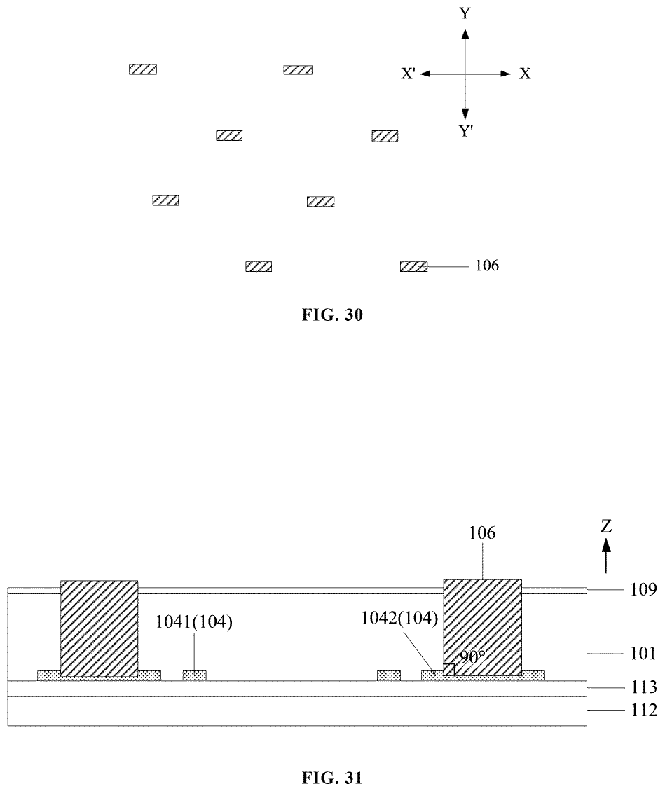

In a fourth step, as shown in FIGS. 30 and 31, second transfer electrodes 106 are formed at positions of the transfer holes by an electroplating process, and deeper transfer holes are filled up to ensure flatness of the layer where the first lead 103 is to be formed subsequently. In particular, since the thick substrate layer 101 is etched through a hard mask of the inorganic layer 109 in the dry etching, another structural feature of this embodiment is that the second transfer electrode 106 in the transfer hole has a taper angle close to 90°.

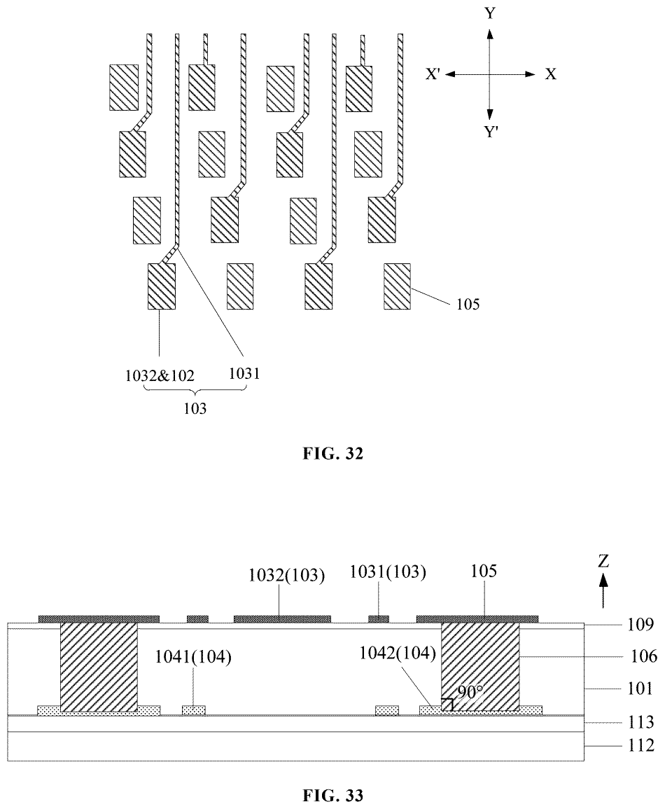

In a fifth step, as shown in FIGS. 32 and 33, a plurality of first leads 103 and a plurality of first transfer electrodes 105 are formed on the inorganic layer 109. Optionally, the layer where the plurality of first leads 103 and the plurality of first transfer electrodes 105 are located is selected to be made of the same material and have the same thickness as the layer where the plurality of second leads 104 are located.

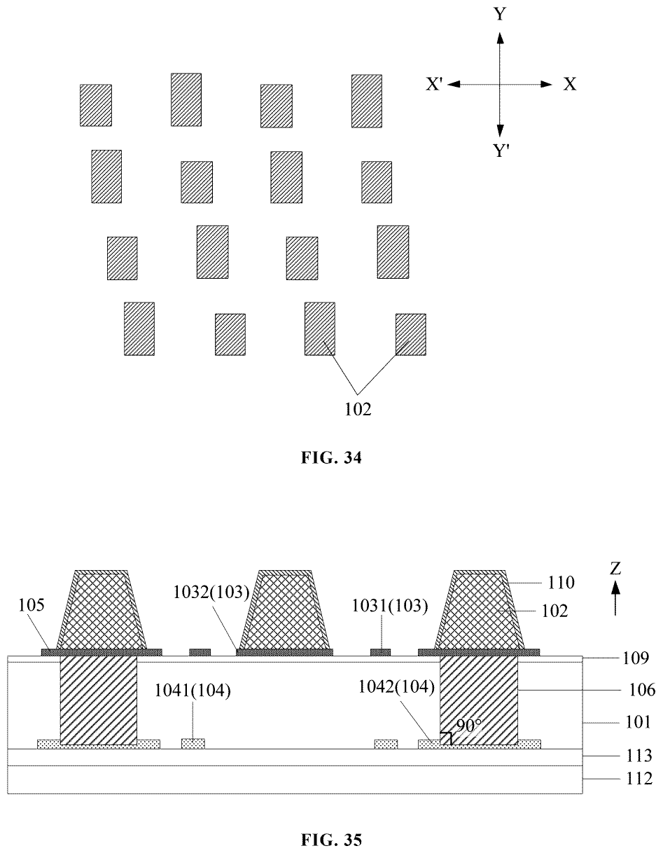

In a sixth step, as shown in FIGS. 34 and 35, a plurality of pads 102, as final bonding pads, are formed on the layer where the plurality of first leads 103 and the plurality of first transfer electrodes 105 are formed. Then, an anti-oxidation layer 110 is plated on a surface of each pad 102. The anti-oxidation layer 110 may be made of Sn or Au or the like, and have a thickness of 0.1 μm to 0.5 μm. Optionally, the plurality of pads 102 may be formed by a subtractive plating process with a relatively low space requirement, and each pad 102 may have a thickness of 3 μm to 10 μm.

In a seventh step, as shown in FIG. 6, the rigid substrate 112 is peeled off by laser lift off (LLO), and the plurality of second leads 104 and the plurality of raised structures 108 can be successfully separated from the rigid substrate 112 due to the presence of the sacrificial layer 113, thereby obtaining the chip on film as shown in FIG. 6.

Optionally, referring to the seventh step in the method for manufacturing the chip on film shown in FIG. 19, solder resin 111 can be further formed on front and back surfaces of the chip on film shown in FIG. 6, which is not described in detail here.

In some embodiments, the chip on film shown in FIG. 8 may be manufactured by the following steps:

In a first step, a sacrificial layer 113 (de-bonding layer, DBL) is coated on a rigid substrate 112 (e.g., a glass substrate). The sacrificial layer 113 may be made of a polyimide system material, and have a thickness of 300 Å to 1000 Å, for example, 300 Å, 400 Å, 500 Å, 600 Å, 700 Å, 800 Å, 900 Å, 1000 Å, or the like.

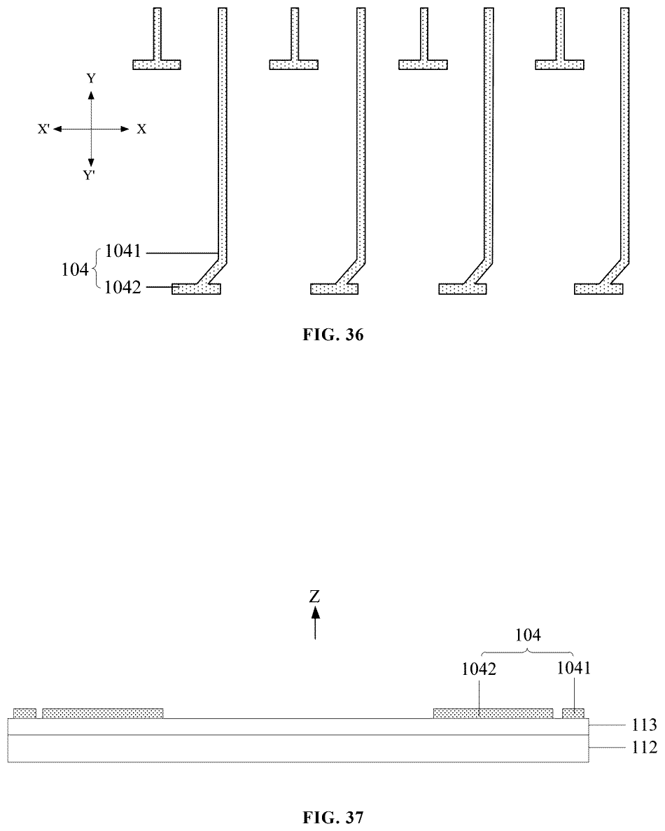

In a second step, as shown in FIGS. 36 and 37, a plurality of second leads 104 are formed on the sacrificial layer 113. Each second lead 104 includes a second wire part 1041 and a second connection part 1042. The second leads 104 are preferably made of a metal material that can be patterned by dry etching (with a small CD bias), such as Ti, Ti/Al/Ti, Mo/Al/Mo, etc., and has a thickness set based on the principle of minimizing the wire resistance. For example, a thickness of the Ti/Al/Ti may be set to 500 Å/6000 Å/500 Å, or the like.

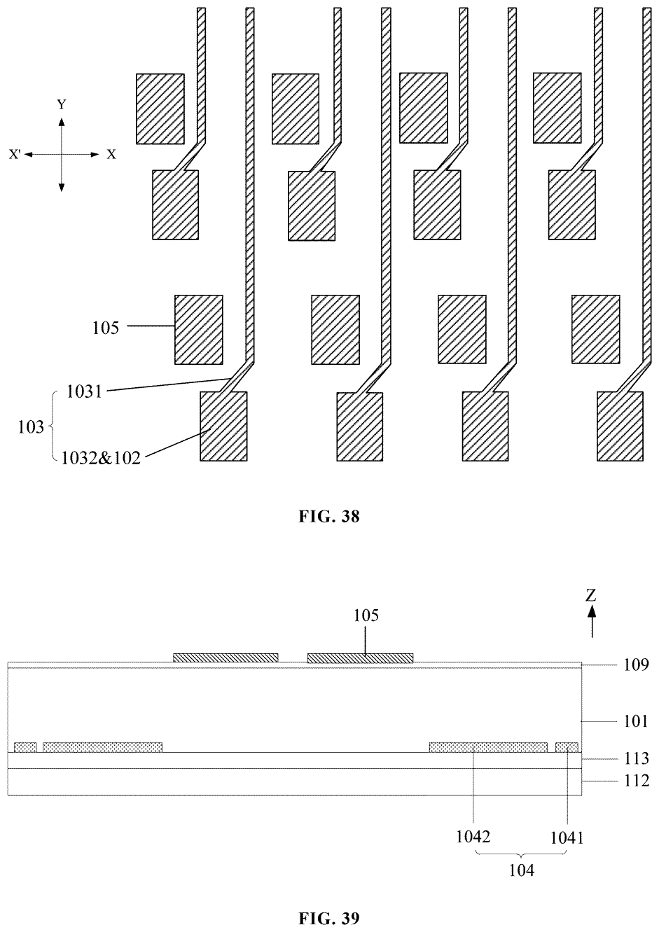

In a third step, as shown in FIGS. 38 and 39, a substrate layer 101 and an inorganic layer 109 are formed on the layer where the second leads 104 are located. In this step, no transfer hole is formed in the substrate layer 101 or the inorganic layer 109. Then, first leads 103 and first transfer electrodes 105, which are disposed in the same layer and made of the same material, are formed on the inorganic layer 109. In particular, the first leads 103 may have the same material and the same structure as the second leads 104.

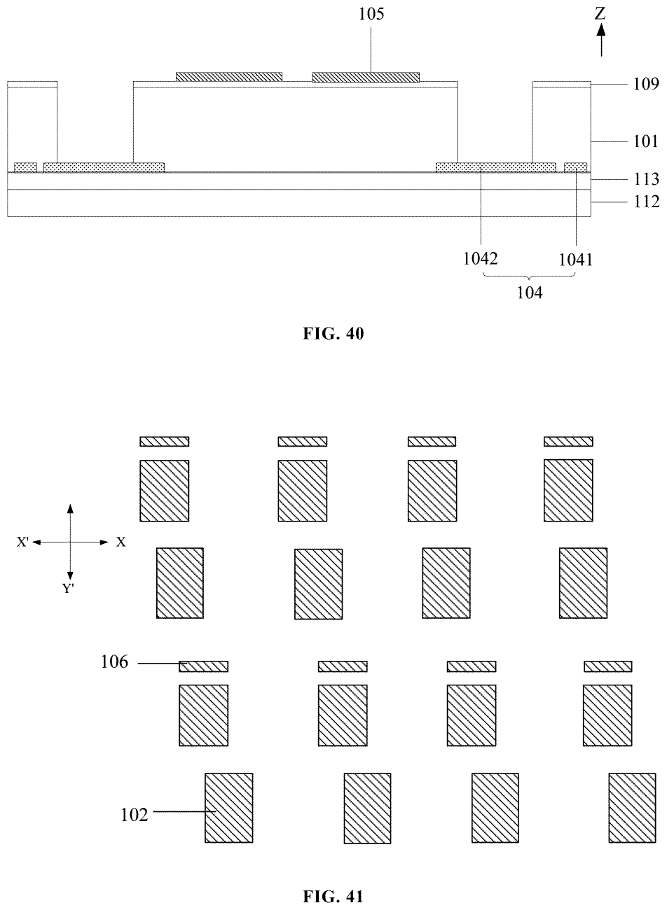

In a fourth step, as shown in FIG. 40, transfer holes running through the substrate layer 101 and the inorganic layer 109 are formed at positions corresponding to respective second connection parts 1042, and etching of the inorganic layer 109, the substrate layer 101, and the upper metal layer D at the positions corresponding to the second connection parts 1042 is implemented by a dry etching process for only one time. In particular, the upper metal layer D is completely removed to ensure that the copper metal can be electroplated subsequently to form the second transfer electrode 106. By forming the substrate layer 101 before forming the second transfer electrode 106, the oxidation effect of the high-temperature process of the substrate layer 101 on the second transfer electrode 106 is effectively avoided.

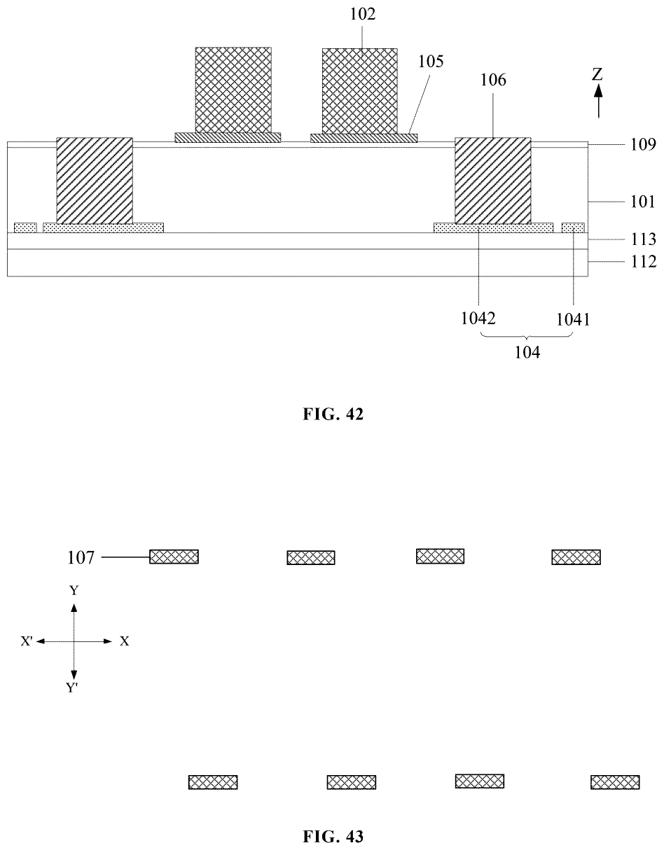

In a fifth step, as shown in FIGS. 41 and 42, second transfer electrodes 106 are formed by additive plating to fill up the transfer holes, while pads 102 for bonding are formed.

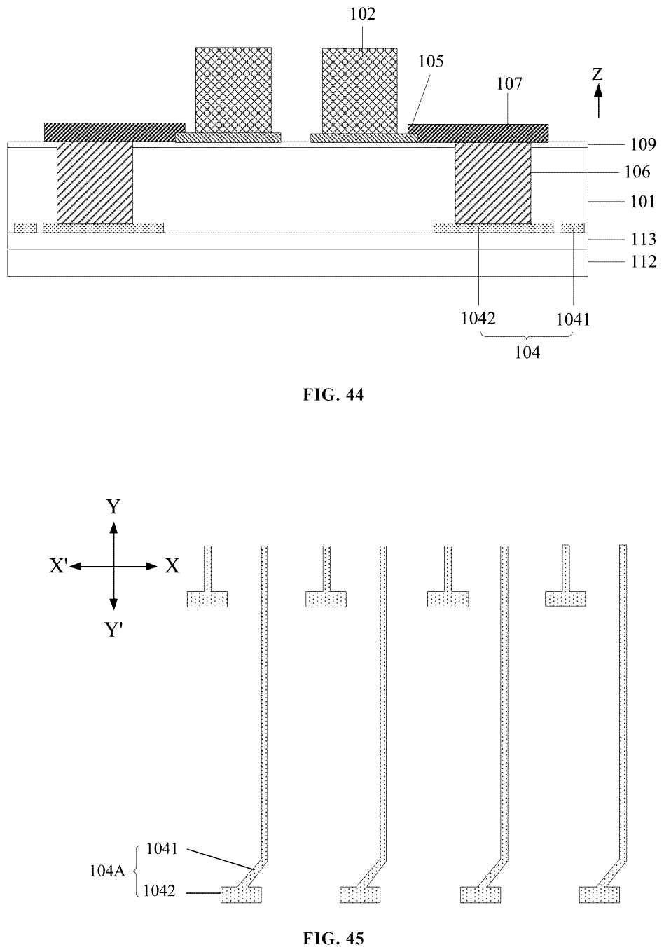

In a sixth step, as shown in FIGS. 43 and 44, third transfer electrodes 107 are formed to connect the first transfer electrodes 105 and the second transfer electrodes 106.

In a seventh step, referring to the sixth step in the method for manufacturing the chip on film shown in FIG. 19, the sacrificial layer 113 and the rigid substrate 112 are peeled off by laser lift off, thereby obtaining the chip on film as shown in FIG. 8. Optionally, referring to the seventh step in the method for manufacturing the chip on film shown in FIG. 19, solder resin 111 can be further formed on front and back surfaces of the chip on film shown in FIG. 8, which is not described in detail here.

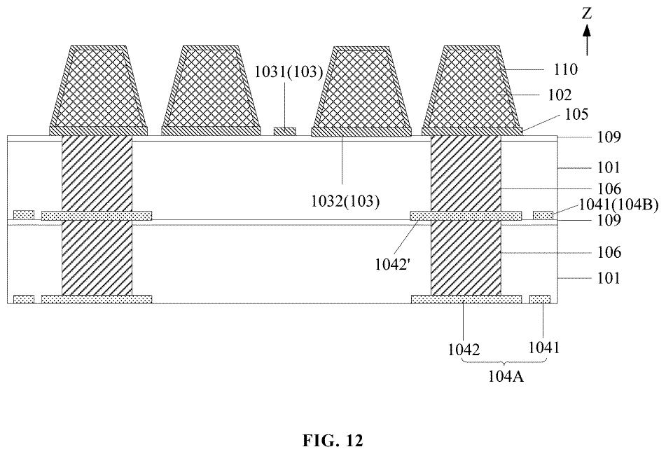

Two layers of second leads 104 are shown in the chip on film of FIG. 12, and for convenience of illustration, in the following method, the second leads 104 formed for a first time are labeled as 104A, while the second leads 104 formed for a second time are labeled as 104B in the following method. Specifically, the chip on film shown in FIG. 12 may be manufactured by the following steps:

In a first step, a sacrificial layer 113 (de-bonding layer, DBL) is coated on a rigid substrate 112 (e.g., a glass substrate). The sacrificial layer 113 may be made of a polyimide system material, and have a thickness of 300 Å to 1000 Å, for example, 300 Å, 400 Å, 500 Å, 600 Å, 700 Å, 800 Å, 900 Å, 1000 Å, or the like.

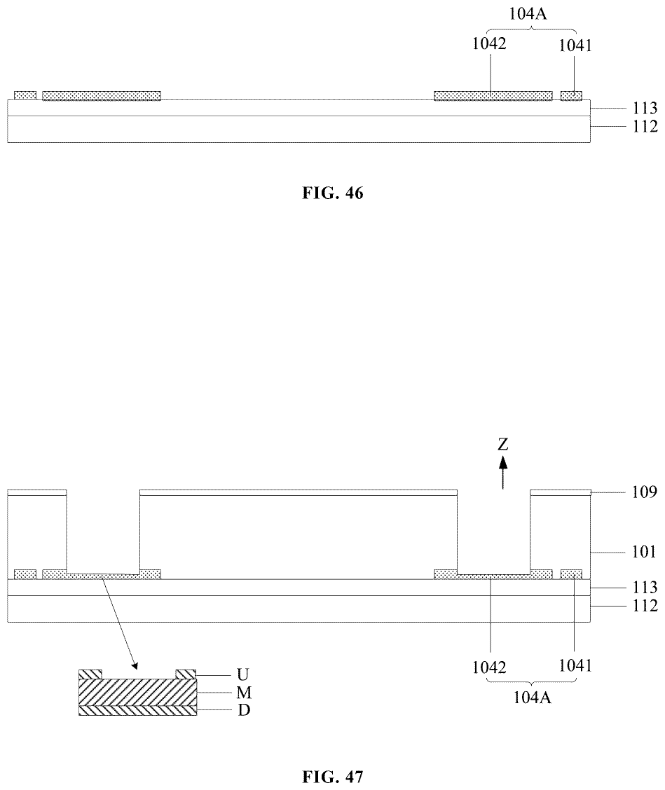

In a second step, as shown in FIGS. 45 and 46, a plurality of second leads 104A are formed for a first time on the sacrificial layer 113. Each second lead 104A in this layer includes a second wire part 1041 and a second connection part 1042. The second lead 104A has a three-layer metal structure, with an intermediate layer of copper and an uppermost/lowermost layer of a metal material that can be removed by a dry etching process, such as molybdenum (Mo), aluminum (Al), titanium (Ti), a molybdenum/nickel/titanium (MTD) alloy or the like, preferably Ti/Cu/Ti, and out of economic considerations, a thickness of the copper layer M may be 3000 Å to 6000 Å, while the upper metal layer U and the lower metal layer D may each have a thickness preferably not more than 500 Å.

In a third step, as shown in FIG. 47, a substrate layer 101 and an inorganic layer 109 are formed on the layer where the second leads 104A are located, transfer holes are formed at positions corresponding to respective second connection parts 1042, and etching of the inorganic layer 109, the substrate layer 101, and the upper metal layer D at the positions corresponding to the second connection parts 1042 is implemented by a dry etching process for only one time. In particular, the upper metal layer D is completely removed to ensure that the copper metal can be electroplated subsequently to form the second transfer electrode 106. By forming the substrate layer 101 before forming the second transfer electrode 106, the oxidation effect of the high-temperature process of the substrate layer 101 on the second transfer electrode 106 is effectively avoided.

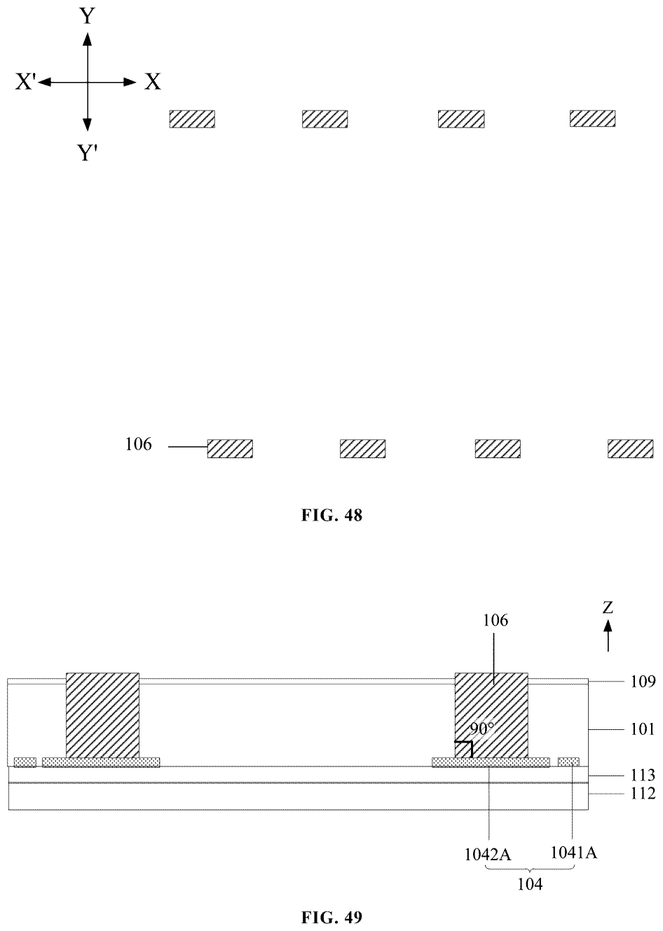

In a fourth step, as shown in FIGS. 48 and 49, second transfer electrodes 106 are formed at positions of the transfer holes by an electroplating process, and deeper transfer holes are filled up to ensure flatness of the layer where the first lead 103 is to be formed subsequently. In particular, since the thick substrate layer 101 is etched through a hard mask of the inorganic layer 109 in the dry etching, another structural feature of this embodiment is that the second transfer electrode 106 in the transfer hole has a taper angle close to 90°.

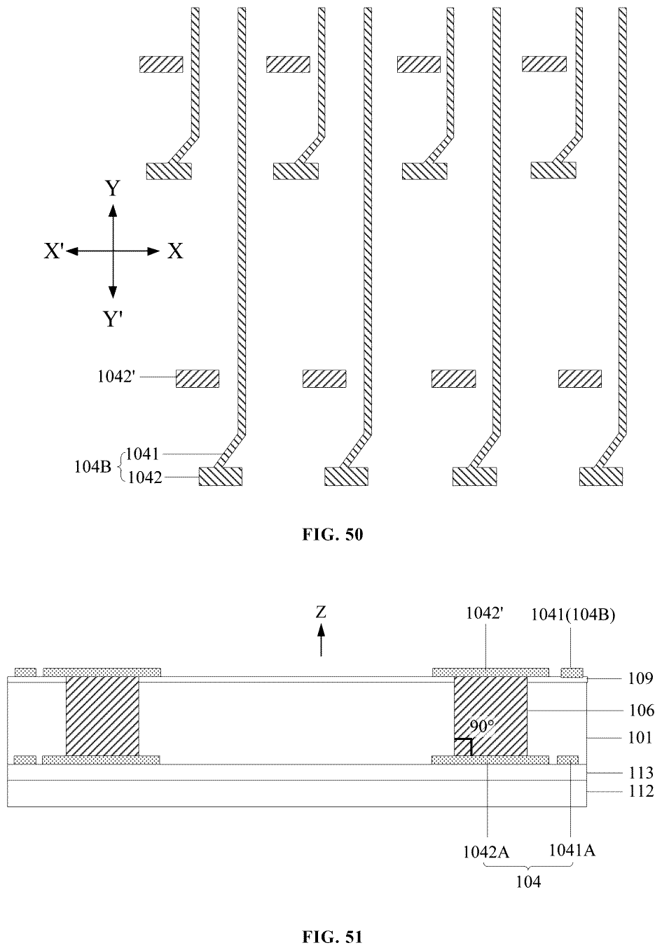

In a fifth step, as shown in FIGS. 50 and 51, a plurality of second leads 104B and transition electrodes 1042′ electrically connected to the second transfer electrodes 106 are formed on the layer where the first transfer electrodes 106 formed in the fourth step are located. The second leads 104B may have the same structure and the same material as the second leads 104A, which is not described in detail here.

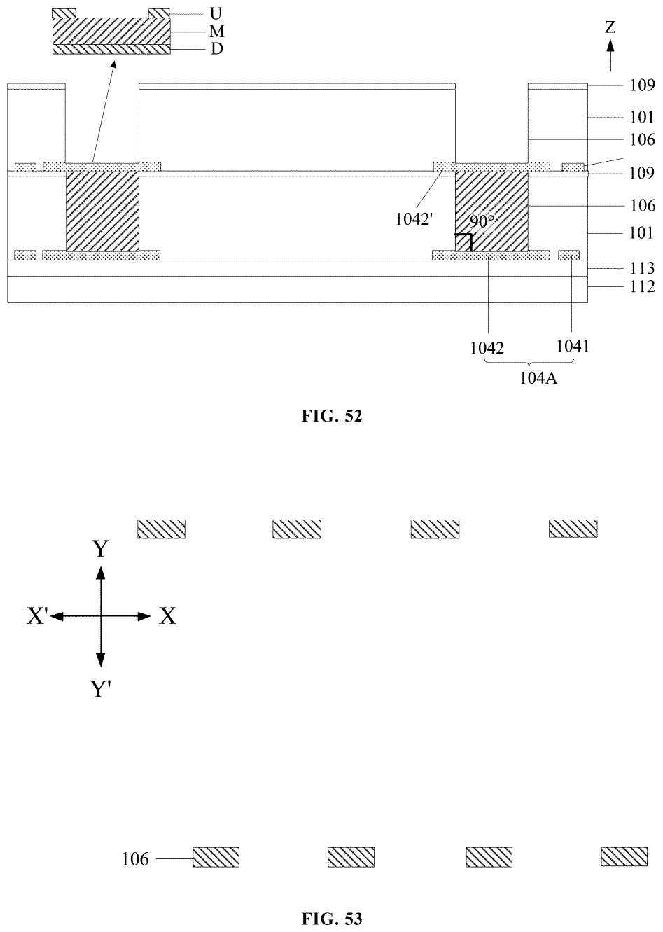

In a sixth step, as shown in FIG. 52, referring to the method in the third step, a substrate layer 101 and an inorganic layer 109 may be sequentially formed on the layer where the second leads 104B are located, and transfer holes running through the substrate layer 101 and the inorganic layer 109 may be formed, while upper metal layers of the transition electrodes 1042′ are etched off at positions corresponding to the transfer holes at the same time, to ensure that the copper metal can be electroplated subsequently to form the second transfer electrode 106.

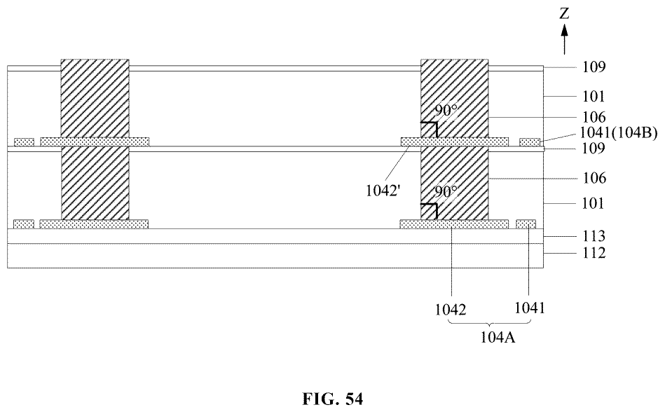

In a seventh step, as shown in FIGS. 53 and 54, referring to the method in the third step, second transfer electrodes 106 each having a taper angle of approximately 90° may be formed in the transfer holes.

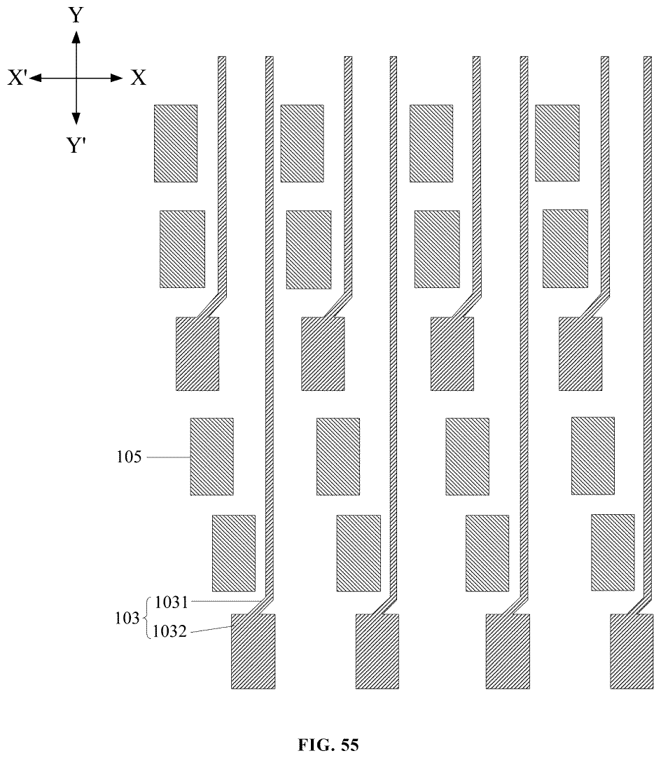

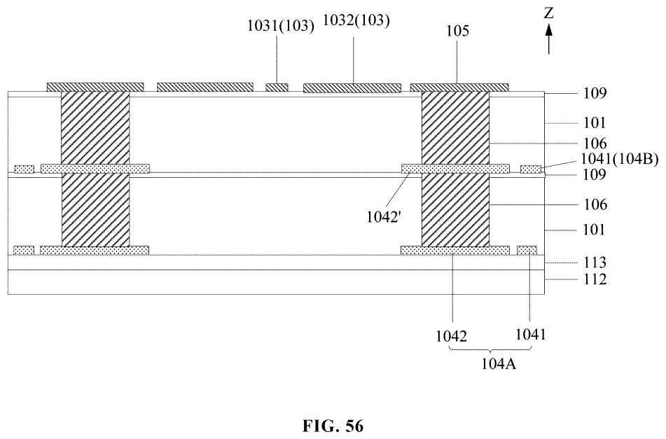

In an eighth step, as shown in FIGS. 55 and 56, a plurality of first leads 103 and a plurality of first transfer electrodes 105 are formed on the second transfer electrodes 106 formed in the seventh step. Optionally, it is selected that the layer where the plurality of first leads 103 and the plurality of first transfer electrodes 105 are located is made of the same material and have the same thickness as the layers where the plurality of second leads 104A, 104B are located.

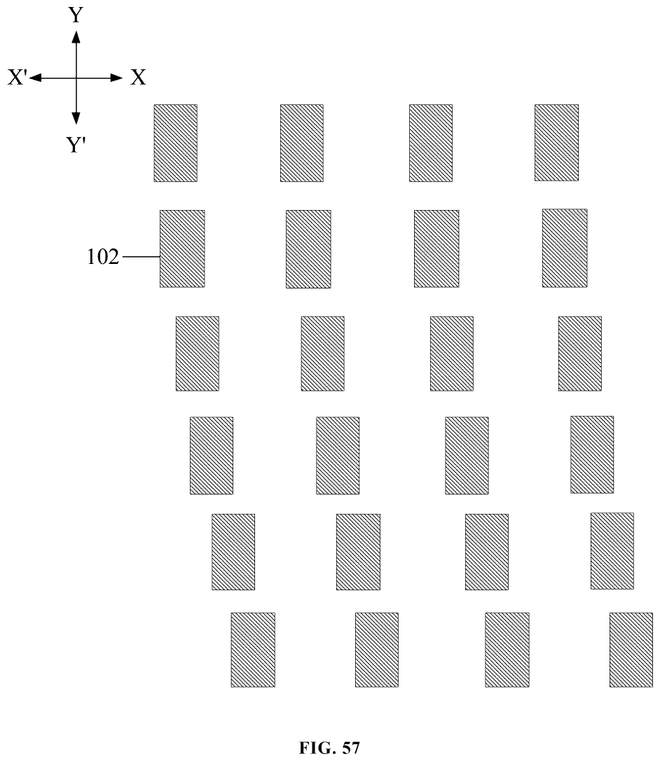

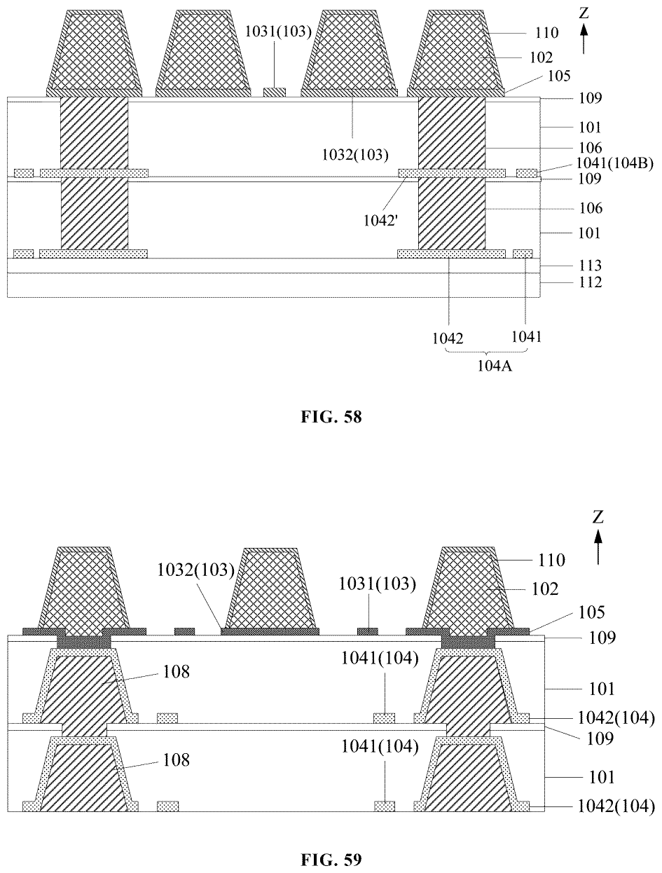

In a ninth step, as shown in FIGS. 57 and 58, a plurality of pads 102, as final bonding pads, are formed on the layer where the plurality of first leads 103 and the plurality of first transfer electrodes 105 are formed. Then, an anti-oxidation layer 110 is plated on a surface of each pad 102. The anti-oxidation layer 110 may be made of Sn or Au or the like, and have a thickness of 0.1 μm to 0.5 μm. Optionally, the plurality of pads 102 may be formed by a subtractive plating process with a relatively low space requirement, and each pad 102 may have a thickness of 3 μm to 10 μm.

In a tenth step, the rigid substrate 112 is peeled off by laser lift off (LLO), and the plurality of second leads 104 can be successfully separated from the rigid substrate 112 due to the presence of the sacrificial layer 113, thereby obtaining the chip on film as shown in FIG. 12.

Optionally, referring to the seventh step in the method for manufacturing the chip on film shown in FIG. 19, solder resin 111 can be further formed on front and back surfaces of the chip on film shown in FIG. 12, which is not described in detail here.

It should be noted that the above description has been made only by taking the first leads 103 and the second leads 104 arranged in two or three layers as an example, but in specific implementations, there may be four or more layers of the first leads 103 and the second leads 104, and in the case of four or more wiring layers, the first leads 103 and the second leads 104 may be arranged in a manner as shown in FIGS. 2 to 12, in which the implementations of FIGS. 2 to 12 may be combined with themselves or with one or more of the others as long as the wiring arrangement schemes in FIGS. 2 to 12 do not conflict with each other. For example, FIG. 59 shows a case of the lead arrangement scheme in the chip on film shown in FIG. 4 combined with the lead arrangement scheme itself. Optionally, the manufacturing method of each film layer in FIG. 59 may refer to the manufacturing method of the same film layer in the chip on film shown in FIG. 4. For example, the manufacturing method of the second lead 104 in FIG. 59 may refer to the manufacturing method of the second lead 104 in the chip on film shown in FIG. 4, which is not described in detail here.

In addition, in the method provided in the embodiments of the present disclosure, the patterning processes involved in formation of the layer structures may include not only some or all of the processes such as deposition, photoresist coating, masking, exposure, development, etching, photoresist stripping and the like, but also other processes, which can be specifically selected based on the pattern to be formed in an actual manufacturing process, and thus is not limited herein. For example, a post-baking process may be further included after development and before etching.

The deposition process may include chemical vapor deposition, plasma enhanced chemical vapor deposition, or physical vapor deposition, which is not limited herein; the mask used in the masking process may be a half tone mask, a single slit mask, or a gray tone mask, which is not limited herein; and the etching may include dry etching or wet etching, which is not limited herein.

Based on the same inventive concept, an embodiment of the present disclosure provides a display apparatus, including the chip on film provided in any one of the embodiments of the present disclosure. Since the display apparatus solves the problem based on a principle similar to that of the chip on film, the implementation of the display apparatus may refer to the embodiments of the chip on film described above, and repeated descriptions are omitted.

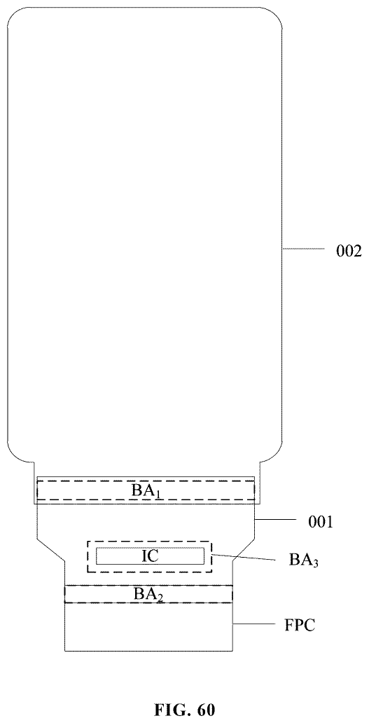

In some embodiments, as shown in FIG. 60, the display apparatus provided in the embodiments of the present disclosure may include a chip on film 001, a display substrate 002, a driver chip IC, and a flexible printed circuit FPC. Optionally, the display substrate 002 is electrically connected to a first bonding region BA1 of the chip on film 001, the flexible printed circuit FPC is electrically connected to a second bonding region BA2 of the chip on film 001, and the driver chip IC is electrically connected to a third bonding region BA3 of the chip on film 001.

In some embodiments, the display apparatus provided in the embodiments of the present disclosure may be: a mobile phone, a tablet, a television, a monitor, a laptop, a digital album, a navigator, a smart watch, a fitness wristband, a personal digital assistant, or any other product or component having a display function. Optionally, the display apparatus provided in the embodiments of the present disclosure includes, but is not limited to: a radio frequency unit, a network module, an audio output/input unit, a sensor, a display unit, a user input unit, an interface unit, a control chip, or the like. Optionally, the control chip is a central processing unit, a digital signal processor, a system on chip (SoC), or the like. For example, the control chip may further include a memory, a power module, or the like, and power supply and signal input/output functions are realized through additionally wires, signal lines, and the like. For example, the control chip may further include a hardware circuit, a computer-executable code, or the like. The hardware circuit may include a conventional very large scale integrated (VLSI) circuit or a gate array, or an existing semiconductor such as a logic chip, a transistor, or any other discrete element. The hardware circuit may further include a field-programmable gate array, a programmable array logic, a programmable logic device, or the like. In addition, it will be understood by those skilled in the art that the above-described structures do not constitute any limitation to the display apparatus provided in the embodiments of the present disclosure. In other words, the display apparatus provided in the embodiments of the present disclosure may include more or fewer components than described, or a combination of some components, or a different arrangement of components.

It will be apparent to those skilled in the art that various changes and variations may be made to the embodiments of the present disclosure without departing from the spirit and scope of the embodiments of the present disclosure. Therefore, if such modifications and variations to the embodiments of the present disclosure are within the scope of the claims of the present disclosure and their equivalents, the present disclosure is also intended to encompass such modifications and variations.

1. A chip on film, comprising:
at least one substrate layer;
a plurality of pads on the at least one substrate layer;
a plurality of first leads on the at least one substrate layer and electrically connected to part of the pads; and
a plurality of second leads on a side of each substrate layer away from a layer where the plurality of pads are located, and electrically connected to the rest of the pads.

2. The chip on film according to claim 1, wherein the plurality of first leads are between the at least one substrate layer and the layer where the plurality of pads are located.

3. The chip on film according to claim 2, wherein each of the first leads comprises a first wire part and a first connection part integrally formed, and the first connection part is in contact with and electrically connected to a corresponding pad.

4. The chip on film according to claim 3, wherein an orthographic projection of the first connection part on the substrate layer substantially coincides with an orthographic projection of the pad electrically connected thereto on the substrate layer, and/or
the chip on film further comprises a plurality of first transfer electrodes each electrically connected between the second lead and the pad.

5. (canceled)

6. The chip on film according to claim 4, wherein the plurality of first transfer electrodes and the plurality of first leads are in the same layer and made of the same material.

7. The chip on film according to claim 6, wherein an orthographic projection of each pad on the substrate layer is within an orthographic projection of one of the first transfer electrodes electrically connected thereto on the substrate layer, and/or
each of the second leads comprises a second wire part and a second connection part integrally formed, and the second connection part is electrically connected to a corresponding pad through a corresponding first transfer electrode.

8. (canceled)

9. The chip on film according to claim 7, wherein the second connection part is in contact with and electrically connected to the first transfer electrode.

10. The chip on film according to claim 9, further comprising a plurality of raised structures on a side of a layer where the plurality of second leads are located away from the layer where the plurality of pads are located, wherein an orthographic projection of each raised structure on the substrate layer substantially coincides with an orthographic projection of a corresponding pad electrically connected to the second connection part on the substrate layer.

11. The chip on film according to claim 10, wherein the orthographic projection of the raised structure on the substrate layer is within an orthographic projection of the second connection part on the substrate layer.

12. The chip on film according to claim 10, wherein in a direction perpendicular to the substrate layer, the substrate layer exceeds the raised structure by a distance within 0.5 μm.

13. The chip on film according to claim 7, further comprising a plurality of second transfer electrodes embedded in the substrate layer, wherein the first transfer electrode is electrically connected to the second connection part through a corresponding second transfer electrode.

14. The chip on film according to claim 13, further comprising a plurality of third transfer electrodes in the same layer as the first transfer electrodes, and each connected between the first transfer electrode and the second transfer electrode.

15. The chip on film according to claim 1, wherein the first lead and the pad are integrally formed.

16. The chip on film according to claim 15, wherein each of the second leads comprises a second wire part and a second connection part integrally formed, and the second connection part is in contact with and electrically connected to a corresponding pad.

17. The chip on film according to claim 16, further comprising a plurality of raised structures on a side of a layer where the plurality of second leads are located away from the layer where the plurality of pads are located, wherein an orthographic projection of each raised structure on the substrate layer has a shape substantially the same as an orthographic projection of a corresponding second lead on the substrate layer, and the orthographic projection of the raised structure on the substrate layer is within the orthographic projection of the second lead on the substrate layer.

18. The chip on film according to claim 1, wherein the raised structures are made of the same material as the pads.

19. The chip on film according to claim 1, wherein orthographic projections of the second leads on the substrate layer and orthographic projections of the first leads on the substrate layer are not overlapped with each other.

20. The chip on film according to claim 1, wherein the plurality of pads are arranged in an array, and any two adjacent rows of the pads are partially staggered along a preset direction.

21. A method for manufacture the chip on film according to claim 1, comprising:
providing a rigid substrate, and forming a sacrificial layer on the rigid substrate;
sequentially forming at least one substrate layer, a plurality of first leads and a plurality of pads on the sacrificial layer, and forming a plurality of second leads each time before forming one substrate layer; wherein the plurality of first leads are electrically connected to part of the pads, and the plurality of second leads are electrically connected to the rest of the pads; and
removing the sacrificial layer to peel off the rigid substrate along with the sacrificial layer, to obtain the chip on film.

22-29. (canceled)

30. A display apparatus, comprising the chip on film according to claim 1.
